(19) United States
(12) Patent Application Publication
(10) Pub. No.: US 2026/0136436 A1
(43) Pub. Date: May 14, 2026

(54) CERAMIC HEATER AND METHOD OF MANUFACTURING CERAMIC HEATER

(71) Applicant: NGK INSULATORS, LTD., Nagoya-City (JP)

(72) Inventors: Keita YAMANA, Nagoya-Shi (JP); Kazuhiro NOBORI, Nagoya-Shi (JP); Keiichi NAKAMURA, Nagoya-Shi (JP); Tetsuhisa ABE, Nagoya-Shi (JP); Yusaku KAWAI, Nagoya-Shi (JP); Naoki YOSHITAKE, Nagoya-Shi (JP)

(73) Assignee: NGK INSULATORS, LTD., Nagoya-City (JP)

(21) Appl. No.: 19/444,419

(22) Filed: Jan. 9, 2026

Related U.S. Application Data
(63) Continuation of application No. PCT/JP2025/001931, filed on Jan. 22, 2025.

(30) Foreign Application Priority Data
Aug. 16, 2024 (JP) 2024-137019

(51) Int. Cl. H05B 3/14

(52) U.S. Cl. CPC H05B 3/143

(57) ABSTRACT

The ceramic heater includes a plate, a shaft, and an auxiliary member. The plate includes a first main surface and a second main surface. The plate has a groove, which is recessed from the second main surface toward the first main surface, and which extends from a start end located on an inner side of the shaft to a terminal end located on an outer side of the shaft. The auxiliary member includes a lid portion and a connecting portion. The lid portion extends along an outer portion of the groove that is located on the outer side of the shaft, and the lid portion is configured to cover the outer portion. The connecting portion is configured to be sandwiched between the plate and the shaft, and to which a distal end portion of the shaft that is a portion surrounding the first opening is allowed to be joined.

### CROSS-REFERENCE TO RELATED APPLICATIONS

This application claims priority from Japanese Patent Application No. 2024-137019 filed on Aug. 16, 2024, the contents of which are incorporated herein by reference in their entirety.

### TECHNICAL FIELD

The present disclosure relates to a ceramic heater and a method of manufacturing a ceramic heater.

### BACKGROUND ART

For example, in a semiconductor manufacturing apparatus, a ceramic heater is used for heating a wafer at the time of performing processing, such as chemical vapor deposition (CVD) or etching, on the wafer. As illustrated in FIG. 41, a ceramic heater 100 includes a plate 101 having a plate shape and a shaft 102 having a cylindrical shape. The plate 101 has a first main surface 103 and a second main surface 104 that are spaced apart from each other in a thickness direction. A wafer is placed on the first main surface 103, and the shaft 102 is joined to the second main surface 104.

A resistance heating element 105, which is formed of a coil containing, for example, molybdenum as a main component, is built into the plate 101, and the entirety of the plate 101 is heated by the resistance heating element 105. In order to confirm that the entirety of the plate 101 is at a uniform temperature, the plate 101 is attached with a first thermocouple for detecting a temperature near an outer periphery, and a second thermocouple for detecting a temperature near the center.

A cavity 106 serving as a thermocouple passage is formed inside the plate 101 so as to extend from the center toward the outer periphery of the plate 101. An opening 107 for inserting the first thermocouple therethrough is also formed in the second main surface 104 of the plate 101 so as to be in communication with the cavity 106. The first thermocouple is inserted into the cavity 106 inside the plate 101 from the opening 107 so that a distal end portion of the first thermocouple is positioned near the outer periphery of the plate 101, thereby detecting a temperature near the outer periphery of the plate 101.

As illustrated in FIG. 42, a related-art ceramic heater is manufactured by bringing the shaft 102 into contact with the second main surface 104 of the plate 101, and joining the plate 101 and the shaft 102 to each other while heating and pressurizing the plate 101 and the shaft 102. A flux 108 is provided between the plate 101 and the shaft 102. In this case, when a load is applied to the plate 101, in which the cavity 106 and the opening 107 are formed, by the shaft 102, a portion 109 of the plate 101, which is located above the cavity 106, is easily bent, resulting in that a problem may occur in which the cavity 106 is crushed by the portion 109, or a problem may occur in which fracture or a crack occurs in the plate 101 due to the portion 109 serving as a trigger.

Meanwhile, in Japanese Patent Application Laid-Open No. 2023-030646, it has been focused that the above-mentioned problems may be caused by a high pressurizing force applied at the time of joining of the plate and the shaft, and with an intermediate ring, which is made of aluminum nitride and contains no yttria, being provided between the plate and the shaft that are made of aluminum nitride containing yttria, the plate and the shaft can be joined to each other with a low pressurizing force. Accordingly, in Japanese Patent Application Laid-Open No. 2023-030646, the above-mentioned problems are prevented.

In Japanese Patent Application Laid-open No. 2012-028332, a thermocouple passage is provided in the plate without forming a cavity in the plate. Specifically, a slide groove extending from the center toward the outer periphery of the plate is formed in the second main surface of the plate, and a guide groove is formed as the thermocouple passage at the bottom of the slide groove. A lid is attached to the slide groove so as to be slidable, and when the guide groove is covered with the lid, the guide groove becomes a closed space blocked from the outside. When a first thermocouple is inserted into this guide groove so that a distal end part of the first thermocouple is positioned near the outer periphery of the plate, a temperature near the outer periphery of the plate is detected by the first thermocouple.

### SUMMARY OF INVENTION

In Japanese Patent Application Laid-Open No. 2023-030646, the plate and the shaft can be joined to each other with a low pressurizing force. However, in Japanese Patent Application Laid-Open No. 2023-030646, the thermocouple passage is provided in the plate by forming a cavity in the plate. As compared to the case of forming a cavity in the plate, providing the thermocouple passage in the plate without forming a cavity in the plate can prevent crushing of the thermocouple passage at the time of joining of the plate and the shaft, and can also prevent occurrence of fracture or a crack in the plate. Accordingly, the technology described in Japanese Patent Application Laid-Open No. 2023-030646 leaves room for improvement in this respect.

In Japanese Patent Application Laid-open No. 2012-028332, a thermocouple passage is provided in the plate without forming a cavity in the plate. However, in Japanese Patent Application Laid-open No. 2012-028332, the shaft and the plate, which are made of a material having high thermal conductivity, are directly joined to each other, and hence heat easily transfers from the plate to the shaft. Such heat removal from the plate to the shaft results in temperature unevenness in the plate, thereby affecting temperature uniformity of the plate. Specifically, the ceramic heater is installed inside a vacuum chamber of a semiconductor manufacturing apparatus, and the inside of the vacuum chamber reaches a high temperature at the time of performing processing, such as chemical vapor deposition (CVD) or etching, on the wafer. The end, which is opposite to the end to be joined to the plate, of the shaft is fixed to a support member via an O-ring. However, the O-ring is cooled in order to maintain sealing performance of the O-ring, because the sealing performance of the O-ring decreases in a high-temperature environment inside the vacuum chamber. When the thermal conductivity of the shaft is satisfactory, heat of the plate easily transfers to the shaft, which affects the temperature uniformity of the plate. Further, in Japanese Patent Application Laid-open No. 2012-028332, in addition to the lid, a tube formed by connecting a plurality of pipes is attached to the plate, which results in a large number of members attached to the plate and lower symmetric property. Accordingly, temperature unevenness easily occurs in the plate, which also affects the temperature uniformity of the plate. Thus, the technology described in Japanese Patent Application Laid-open No. 2012-028332 leaves room for improvement in enhancement of the temperature uniformity of the plate.

In view of the foregoing, one object of the present disclosure is to provide: a ceramic heater that enables preventing occurrence of, for example, crushing of a thermocouple passage or fracture of a plate at the time of joining of the plate and a shaft, and improving temperature uniformity of the plate; and a method of manufacturing a ceramic heater.

According to the present disclosure, there is provided a ceramic heater including a plate having a plate shape, a shaft having a cylindrical shape, and an auxiliary member having a plate shape. The plate includes a first main surface on which a wafer is to be placed, a second main surface spaced apart from the first main surface in a thickness direction, and a resistance heating element built into the plate and configured to generate heat through energization. The shaft has a first opening and a second opening that are respectively located at both ends in an axial direction, and the shaft is configured to support the plate at the second main surface. The auxiliary member is configured to be joined to the plate. The plate has a groove, which is recessed from the second main surface toward the first main surface, and which extends from a start end located on an inner side of the shaft to a terminal end located on an outer side of the shaft. The auxiliary member includes a lid portion and a connecting portion. The lid portion extends along an outer portion of the groove that is located on the outer side of the shaft, and the lid portion is configured to cover the outer portion. The connecting portion is configured to be sandwiched between the plate and the shaft, and to which a distal end portion of the shaft that is a portion surrounding the first opening is allowed to be joined.

According to the present disclosure, there is provided a method of manufacturing a ceramic heater, the method including: forming, in a plate having a plate shape, which includes a resistance heating element built into the plate and configured to generate heat through energization, a groove that is recessed from a second main surface toward a first main surface out of the first main surface and the second main surface of the plate, which are spaced apart from each other in a thickness direction, and that extends from the center of the second main surface toward an outer periphery of the second main surface; installing, onto the plate, an auxiliary member having a plate shape, which includes a lid portion and a connecting portion having an annular shape, so that an outer portion of the groove, which is a portion near the outer periphery of the second main surface, is covered with the lid portion that extends along the outer portion, and an inner portion of the groove, which is a portion near the center of the second main surface, is located on an inner side of the connecting portion; installing a shaft having a cylindrical shape onto the auxiliary member so that a distal end portion of the shaft, which is an area surrounding a first opening out of the first opening and a second opening of the shaft that are respectively located at both ends of the shaft in an axial direction, abuts against the connecting portion; and simultaneously joining the shaft and the connecting portion of the auxiliary member, and the connecting portion of the auxiliary member and the plate to each other, while applying a pressure to the shaft, and joining the lid portion of the auxiliary member and the plate to each other while applying a load to the lid portion of the auxiliary member by a pressing member.

According to the present disclosure, it is possible to provide a ceramic heater that enables preventing occurrence of, for example, crushing of the groove serving as a thermocouple passage or fracture of the plate at the time of joining of the plate and the shaft, and improving temperature uniformity of the plate.

### BRIEF DESCRIPTION OF DRAWINGS

FIG. 1 is a perspective view of a ceramic heater according to a first embodiment of the present disclosure.

FIG. 2 is an exploded perspective view of the ceramic heater according to the first embodiment.

FIG. 3 is a plan view of the ceramic heater according to the first embodiment.

FIG. 4 is a bottom view of the ceramic heater according to the first embodiment.

FIG. 5 is a front view of the ceramic heater according to the first embodiment.

FIG. 6 is a rear view of the ceramic heater according to the first embodiment.

FIG. 7 is a right side view of the ceramic heater according to the first embodiment.

FIG. 8 is a left side view of the ceramic heater according to the first embodiment.

FIG. 9 is an enlarged sectional view for illustrating a part of the ceramic heater according to the first embodiment when cut along a vertical plane including the line A-A in FIG. 4.

FIG. 10 is a sectional view for illustrating a schematic configuration with the ceramic heater according to the first embodiment being used in a semiconductor manufacturing apparatus.

FIG. 11 is a bottom view of a plate.

FIG. 12 is a plan view of an auxiliary member.

FIG. 13 is a front view of the auxiliary member.

FIG. 14 is a sectional view for illustrating a part of a manufacturing process of the ceramic heater according to the first embodiment.

FIG. 15 is an exploded perspective view of a ceramic heater according to a second embodiment of the present disclosure.

FIG. 16 is a plan view of the ceramic heater according to the second embodiment.

FIG. 17 is a bottom view of the ceramic heater according to the second embodiment.

FIG. 18 is a front view of the ceramic heater according to the second embodiment.

FIG. 19 is a rear view of the ceramic heater according to the second embodiment.

FIG. 20 is a right side view of the ceramic heater according to the second embodiment.

FIG. 21 is a left side view of the ceramic heater according to the second embodiment.

FIG. 22 is an enlarged sectional view for illustrating a part of the ceramic heater according to the second embodiment when cut along a vertical plane including the line A-A in FIG. 17.

FIG. 23 is an exploded perspective view of a ceramic heater according to a third embodiment of the present disclosure.

FIG. 24 is a plan view of the ceramic heater according to the third embodiment.

FIG. 25 is a bottom view of the ceramic heater according to the third embodiment.

FIG. 26 is a front view of the ceramic heater according to the third embodiment.

FIG. 27 is a rear view of the ceramic heater according to the third embodiment.

FIG. 28 is a right side view of the ceramic heater according to the third embodiment.

FIG. 29 is a left side view of the ceramic heater according to the third embodiment.

FIG. 30 is an enlarged sectional view for illustrating a part of the ceramic heater according to the third embodiment when cut along a vertical plane including the line A-A in FIG. 25.

FIG. 31 is an enlarged sectional view for illustrating a part of the ceramic heater according to the third embodiment when cut along a vertical plane including the line B-B in FIG. 25.

FIG. 32 is a bottom view of a plate, which is a constituent member of the ceramic heater according to the third embodiment.

FIG. 33 is a plan view of a modification example of the auxiliary member.

FIG. 34 is a bottom view of the modification example of the auxiliary member.

FIG. 35 is a front view of the modification example of the auxiliary member.

FIG. 36A is a sectional view of the modification example of the auxiliary member when cut along a vertical plane including the line A-A in FIG. 33, and FIG. 36B is a sectional view of the modification example of the auxiliary member when cut along a vertical plane including the line B-B in FIG. 33.

FIG. 37 is an enlarged sectional view for illustrating a part of the ceramic heater according to the third embodiment using the modification example of the auxiliary member.

FIG. 38 is an enlarged sectional view for illustrating a part of the ceramic heater according to the third embodiment using the modification example of the auxiliary member.

FIG. 39 is an enlarged sectional view for illustrating a part of a ceramic heater according to a modification example.

FIG. 40 is an enlarged sectional view for illustrating a part of a ceramic heater according to a modification example.

FIG. 41 is a sectional view of a related-art ceramic heater.

FIG. 42 is a sectional view for illustrating a part of a manufacturing process of the related-art ceramic heater.

### DETAILED DESCRIPTION

### Description of Embodiments of the Present Disclosure

Embodiments of a ceramic heater and a method of manufacturing a ceramic heater according to the present disclosure are first listed and described.

A ceramic heater according to a first aspect of the present disclosure includes a plate having a plate shape, a shaft having a cylindrical shape, and an auxiliary member having a plate shape. The plate includes a first main surface on which a wafer is to be placed, a second main surface spaced apart from the first main surface in a thickness direction, and a resistance heating element built into the plate and configured to generate heat through energization. The shaft has a first opening and a second opening that are respectively located at both ends in an axial direction, and the shaft is configured to support the plate at the second main surface. The auxiliary member is configured to be joined to the plate. The plate has a groove, which is recessed from the second main surface toward the first main surface, and which extends from a start end located on an inner side of the shaft to a terminal end located on an outer side of the shaft. The auxiliary member includes a lid portion and a connecting portion. The lid portion extends along an outer portion of the groove that is located on the outer side of the shaft, and the lid portion is configured to cover the outer portion. The connecting portion is configured to be sandwiched between the plate and the shaft, and to which a distal end portion of the shaft that is a portion surrounding the first opening is allowed to be joined.

In the ceramic heater according to the first aspect, no cavity is formed in the plate as a thermocouple passage for inserting a thermocouple inside the plate, and instead thereof, the groove that is recessed from the second main surface toward the first main surface of the plate is formed. The outer portion of the groove is covered with the lid portion of the auxiliary member joined to the plate, so that an internal space of the outer portion is blocked from an external space thereof. The inner portion of the groove is surrounded by the connecting portion of the auxiliary member joined to the plate, and the shaft is joined to the connecting portion of the auxiliary member so that an internal space of the inner portion is blocked from an external space thereof. Accordingly, the thermocouple inserted into the groove is isolated from the external space, and thus with the ceramic heater according to the first aspect, a temperature near an outer periphery of the plate is detected with high accuracy by the thermocouple.

Further, in the ceramic heater according to the first aspect, bending hardly occurs in a part of each of the auxiliary member and the plate, even when a load is applied to the auxiliary member and the plate at the time of joining of the auxiliary member and the shaft to the plate. Accordingly, with the ceramic heater according to the first aspect, occurrence of, for example, crushing of the groove serving as the thermocouple passage or fracture of the plate at the time of joining of the plate and the shaft is prevented.

Further, in the ceramic heater according to the first aspect, the shaft is joined to the connecting portion of the auxiliary member, and the connecting portion is joined to the plate, so that the shaft is indirectly joined to the plate with the connecting portion sandwiched therebetween. In this manner, with the auxiliary member being arranged between the plate and the shaft, the joining interface between the plate and the shaft increases, as compared to a case in which the shaft is directly joined to the plate. The joining interface may become an obstacle to heat conduction, and hence the increase in the joining interface reduces heat removal from the plate to the shaft. Accordingly, with the ceramic heater according to the first aspect, temperature unevenness in the plate can be suppressed, and hence temperature uniformity of the plate can be improved. In addition, with the ceramic heater according to the first aspect, only the auxiliary member is attached to the plate, that is, the number of members attached to the plate is small. Accordingly, temperature unevenness in the plate can be suppressed, resulting in that the temperature uniformity of the plate can be improved.

As a ceramic heater according to a second aspect of the present disclosure, the ceramic heater according to the above-mentioned first aspect may be configured such that: the plate has a recess portion, which is recessed from the second main surface toward the first main surface, and into which the auxiliary member is allowed to be fitted; and at least a portion of the groove of the plate is formed in a bottom surface of the recess portion so as to be recessed toward the first main surface. In the ceramic heater according to the second aspect, with such a configuration, positioning of the auxiliary member relative to the plate is facilitated, and accordingly positioning of the shaft relative to the plate is facilitated.

As a ceramic heater according to a third aspect of the present disclosure, the ceramic heater according to the above-mentioned second aspect may be configured such that a gap is defined in at least a portion between a side surface of the auxiliary member and a side surface of the recess portion of the plate. In the ceramic heater according to the third aspect, with such a configuration, lateral heat conduction between the plate and the auxiliary member can be suppressed. Accordingly, heat of the plate hardly transfers to the shaft via the auxiliary member, resulting in that the temperature uniformity of the first main surface, on which the wafer is to be placed, can be improved.

As a ceramic heater according to a fourth aspect of the present disclosure, the ceramic heater according to the above-mentioned second or third aspect may be configured such that: the connecting portion has an annular shape that allows the distal end portion of the shaft to abut against the connecting portion; the recess portion of the plate includes a first recess portion, into which the lid portion is allowed to be fitted, and a second recess portion, into which the connecting portion is allowed to be fitted and which is continuous with the first recess portion; the second recess portion is formed in an annular shape so as to have an inner peripheral surface that faces an inner peripheral surface of the connecting portion; and the groove of the plate includes a first groove portion formed in a bottom surface of the first recess portion and a bottom surface of the second recess portion so as to be recessed toward the first main surface, and a second groove portion formed in the second main surface of the plate on the inner side of the shaft so as to be recessed toward the first main surface, the first groove portion and the second groove portion being in communication with each other. In the ceramic heater according to the fourth aspect, with such a configuration, a volume of the auxiliary member can be decreased, resulting in that a ratio of the auxiliary member to the entire plate including the auxiliary member is reduced.

As a ceramic heater according to a fifth aspect of the present disclosure, the ceramic heater according to the above-mentioned fourth aspect may be configured such that a gap is defined in at least a portion between the inner peripheral surface of the connecting portion of the auxiliary member and the inner peripheral surface of the second recess portion of the plate. In the ceramic heater according to the fifth aspect, with such a configuration, lateral heat conduction between the plate and the auxiliary member can be suppressed. Accordingly, heat of the plate hardly transfers to the shaft via the auxiliary member, resulting in that the temperature uniformity of the first main surface, on which the wafer is to be placed, can be improved.

As a ceramic heater according to a sixth aspect of the present disclosure, the ceramic heater according to the above-mentioned second or third aspect may be configured such that: the connecting portion has an annular shape that allows the distal end portion of the shaft to abut against the connecting portion; the recess portion of the plate includes a first recess portion, into which the lid portion is allowed to be fitted, and a second recess portion, into which the connecting portion is allowed to be fitted and which is continuous with the first recess portion; the second recess portion is formed so as to have a flat bottom surface, against which the connecting portion is allowed to abut, and an outer peripheral surface that faces an outer peripheral surface of the connecting portion; a space is present on an inner side of the connecting portion on the flat bottom surface; and the groove of the plate is formed in a bottom surface of the first recess portion and a bottom surface of the second recess portion so as to be recessed toward the first main surface. In the ceramic heater according to the sixth aspect, with such a configuration, lateral heat conduction between the plate and the auxiliary member can be suppressed, and heat transfer from the plate to the auxiliary member due to thermal radiation from the plate can also be suppressed. Accordingly, heat transfer from the plate to the shaft via the auxiliary member is effectively suppressed, resulting in that the temperature uniformity of the first main surface, on which the wafer is to be placed, can be further improved.

As a ceramic heater according to a seventh aspect of the present disclosure, the ceramic heater according to any one of the above-mentioned first to sixth aspects may be configured such that at least a portion on a first surface side, which is allowed to abut against the plate, of at least one of the lid portion or the connecting portion of the auxiliary member has a tapered shape. In the ceramic heater according to the seventh aspect, with such a configuration, longitudinal heat conduction between the plate and the auxiliary member can be suppressed. Accordingly, heat of the plate hardly transfers to the shaft via the auxiliary member, resulting in that the temperature uniformity of the first main surface, on which the wafer is to be placed, can be further improved.

As a ceramic heater according to an eighth aspect of the present disclosure, the ceramic heater according to the above-mentioned seventh aspect may be configured such that at least a portion on the first surface side of the inner peripheral surface of the connecting portion is a first inclined surface inclined toward the outer peripheral surface of the connecting portion. In the ceramic heater according to the eighth aspect, with such a configuration, when the connecting portion of the auxiliary member is pressed and joined to the plate at the time of manufacturing the ceramic heater, stress generated in the connecting portion can be distributed, resulting in that a risk of damage to the connecting portion can be reduced.

As a ceramic heater according to a ninth aspect of the present disclosure, the ceramic heater according to the above-mentioned eighth aspect may be configured such that: at least a portion on the first surface side of the outer peripheral surface of the connecting portion is a second inclined surface inclined toward the inner peripheral surface of the connecting portion; and the first inclined surface is inclined over a longer distance as compared to the second inclined surface. In the ceramic heater according to the ninth aspect, with such a configuration, when the connecting portion of the auxiliary member is pressed and joined to the plate at the time of manufacturing the ceramic heater, stress generated in the connecting portion can be more satisfactorily distributed, resulting in that the risk of damage to the connecting portion can be effectively reduced.

As a ceramic heater according to a tenth aspect of the present disclosure, the ceramic heater according to any one of the above-mentioned third to ninth aspects may be configured such that at least one of the gap formed between the side surface of the auxiliary member and the side surface of the recess portion of the plate or the gap formed between the inner peripheral surface of the connecting portion and the inner peripheral surface of the second recess portion of the plate is filled with a filling material. In the ceramic heater according to the tenth aspect, with such a configuration, a risk of unrequired substances, such as machining chips and dust, accumulating in the gap of the ceramic heater can be reduced. Accordingly, such a concern can be eliminated that, for example, at the time of performing processing, such as chemical vapor deposition (CVD) or etching, on the wafer in a semiconductor manufacturing apparatus, unrequired substances may scatter toward the wafer and adversely affect the wafer processing. Further, a concern that, for example, gas used for wafer processing may enter the gap and cause corrosion on a joining surface between the auxiliary member and the plate can also be eliminated.

As a ceramic heater according to an eleventh aspect of the present disclosure, the ceramic heater according to any one of the above-mentioned first to tenth aspects may be configured such that: the plate and the shaft each contain aluminum nitride as a main component; and the auxiliary member contains aluminum nitride as a main component and contains no yttria. The plate, the shaft, and the auxiliary member are integrated by, for example, diffusion joining using a flux including a rare earth component. With the auxiliary member containing no yttria, diffusion of the rare earth component of the flux is promoted near the joining interface between the auxiliary member and the plate and near the joining interface between the auxiliary member and the shaft, at the time of joining of the plate and the auxiliary member, and joining of the shaft and the auxiliary member. Accordingly, with the ceramic heater according to the eleventh aspect, joining of the plate and the auxiliary member and joining of the shaft and the auxiliary member can be performed at a low temperature and with a low load.

A method of manufacturing a ceramic heater according to a first aspect of the present disclosure includes: forming, in a plate having a plate shape, which includes a resistance heating element that is built into the plate and that generates heat through energization, a groove that is recessed from a second main surface toward a first main surface out of the first main surface and the second main surface of the plate, which are spaced apart from each other in a thickness direction, and that extends from the center of the second main surface toward an outer periphery of the second main surface; installing, onto the plate, an auxiliary member having a plate shape, which includes a lid portion and a connecting portion having an annular shape, so that an outer portion of the groove, which is a portion near the outer periphery of the second main surface, is covered with the lid portion that extends along the outer portion, and an inner portion of the groove, which is a portion near the center of the second main surface, is located on an inner side of the connecting portion; installing a shaft having a cylindrical shape onto the auxiliary member so that a distal end portion of the shaft, which is an area surrounding a first opening out of the first opening and a second opening of the shaft that are respectively located at both ends of the shaft in an axial direction, abuts against the connecting portion; and simultaneously joining the shaft and the connecting portion of the auxiliary member, and the connecting portion of the auxiliary member and the plate to each other, while applying a pressure to the shaft, and joining the lid portion of the auxiliary member and the plate to each other while applying a load to the lid portion of the auxiliary member by a pressing member.

In the method of manufacturing a ceramic heater according to the first aspect, while the distal end portion of the shaft presses the connecting portion of the auxiliary member against the plate, the pressing member simultaneously presses the lid portion of the auxiliary member against the plate, so that the plate, the auxiliary member, and the shaft are joined to each other with single pressing. Accordingly, with the method of manufacturing a ceramic heater according to the first aspect, the plate, the auxiliary member, and the shaft can be easily integrated, and the manufacturing cost of the ceramic heater can be reduced.

In addition, joining of the plate, the auxiliary member, and the shaft is performed in a heated state with heat applied. However, the resistance heating element built into the plate contains, for example, molybdenum as a main component, and hence electric resistance of the resistance heating element changes due to carbonization or the like when the resistance heating element is heated. Accordingly, it is desirable to suppress a change in the electric resistance of the resistance heating element in order to uniformly heat the plate by the resistance heating element. With the plate, the auxiliary member, and the shaft being able to be joined to each other with single pressing as in the method of manufacturing a ceramic heater according to the first aspect, variations in the electric resistance of the resistance heating element can be suppressed. Thus, with the method of manufacturing a ceramic heater according to the first aspect, the temperature uniformity of the plate can be improved.

Further, in the method of manufacturing a ceramic heater according to the first aspect, no cavity is formed in the plate as a thermocouple passage for inserting a thermocouple into the plate, and instead thereof, a groove that is recessed from the second main surface toward the first main surface of the plate is formed. Accordingly, bending hardly occurs in a part of each of the auxiliary member and the plate, even when a load is applied to the auxiliary member and the plate at the time of joining of the auxiliary member and the shaft to the plate. Thus, with the method of manufacturing a ceramic heater according to the first aspect, occurrence of, for example, crushing of the groove serving as the thermocouple passage or fracture of the plate at the time of joining of the plate and the shaft can be prevented.

As a method of manufacturing a ceramic heater according to a second aspect of the present disclosure, the method of manufacturing a ceramic heater according to the above-mentioned first aspect may be configured such that at least a portion on the first surface side, which is allowed to abut against the plate, of the inner peripheral surface of the connecting portion is inclined toward the outer peripheral surface of the connecting portion. In the method of manufacturing a ceramic heater according to the second aspect, with such a configuration, when the connecting portion of the auxiliary member is pressed and joined to the plate at the time of manufacturing the ceramic heater, stress generated in the connecting portion can be distributed, resulting in that a risk of damage to the connecting portion can be reduced.

### DETAILS OF EMBODIMENTS OF THE PRESENT DISCLOSURE

Next, embodiments of a ceramic heater according to the present disclosure are described with reference to the drawings. In the drawings referred to below, the same or corresponding parts are denoted by the same reference symbols, and description thereof is not repeated.

### First Embodiment

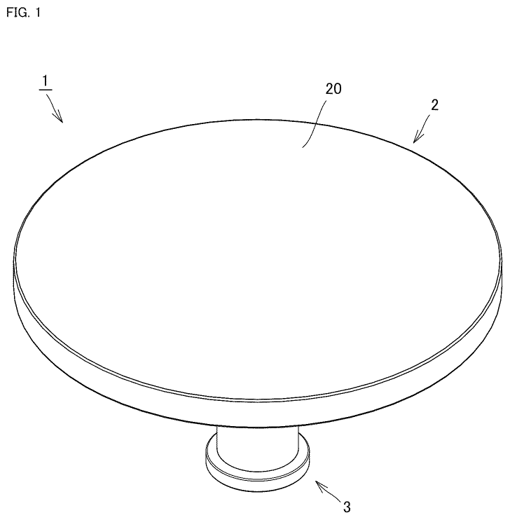

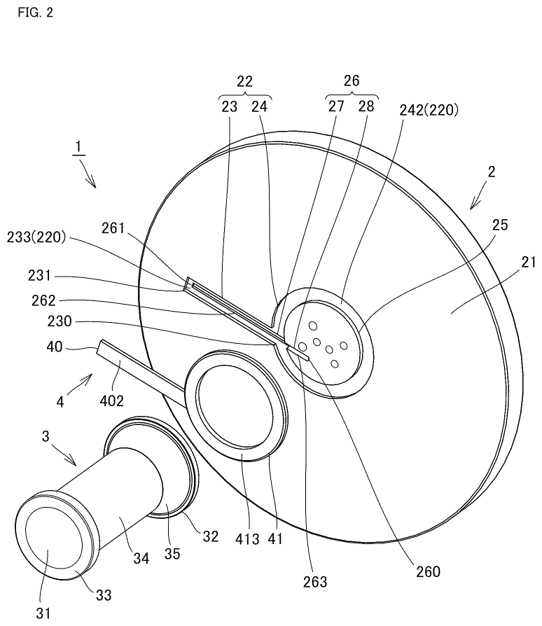

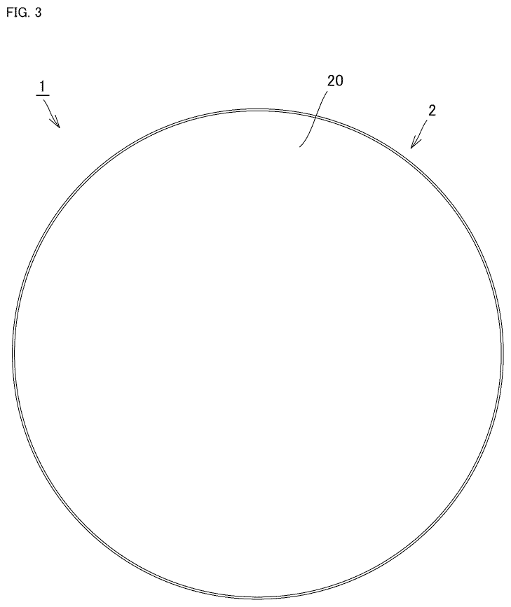

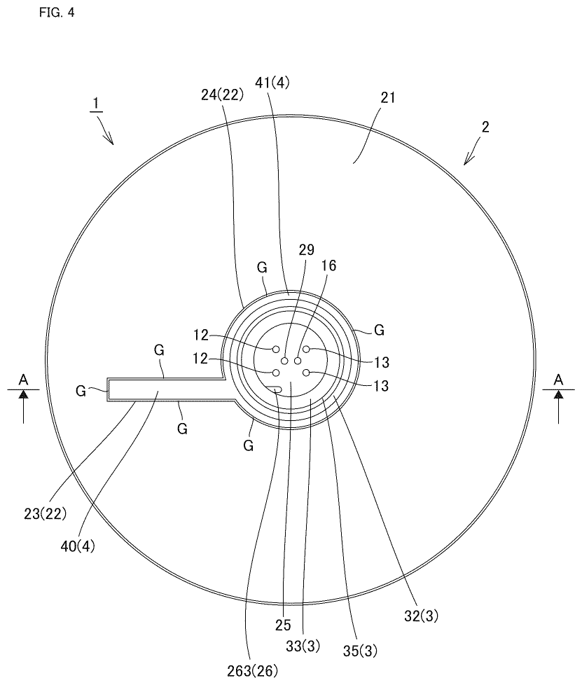

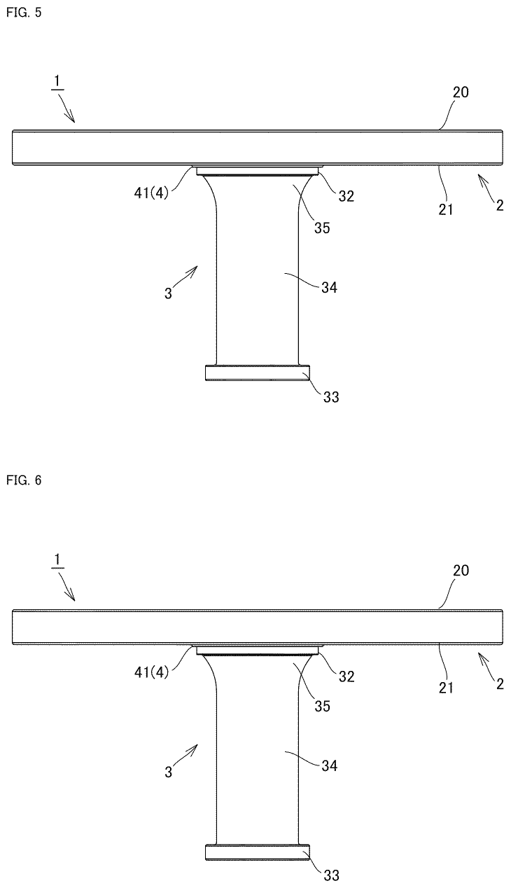

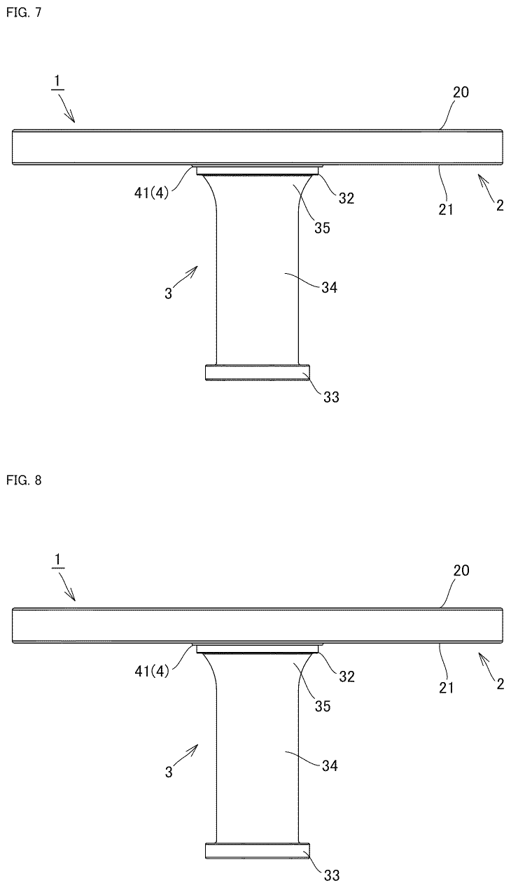

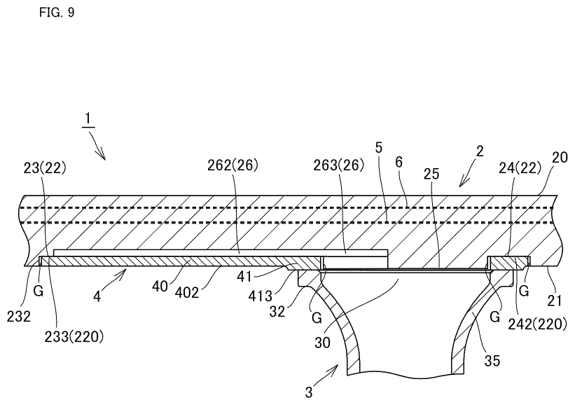

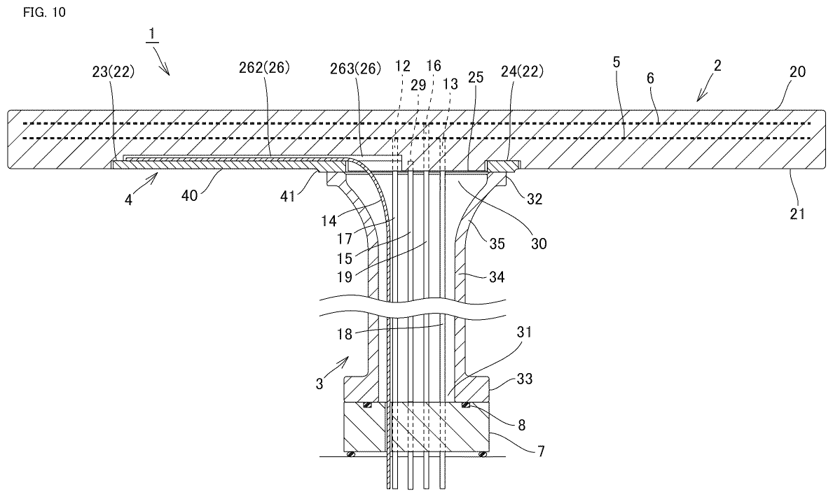

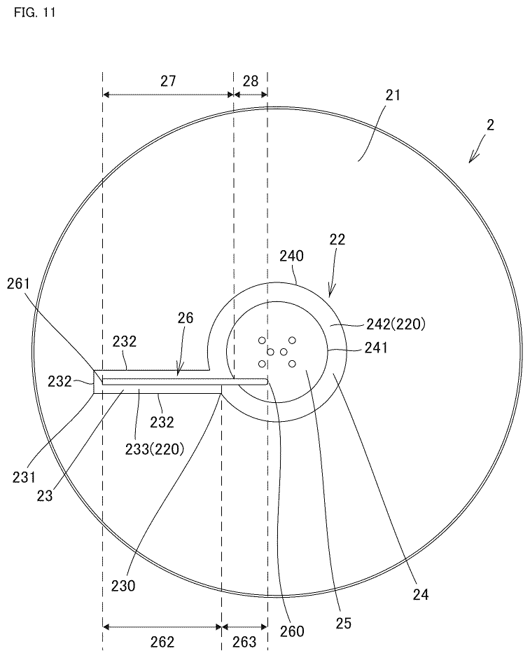

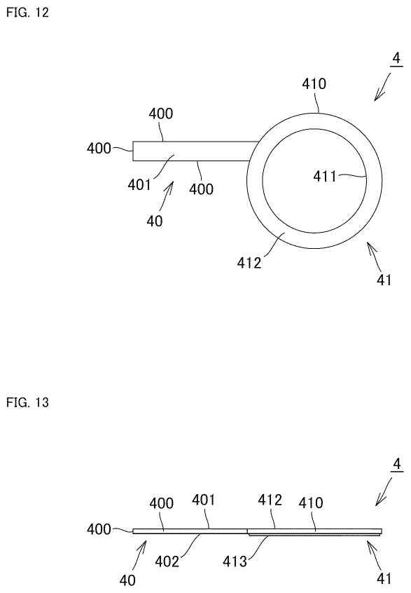

FIG. 1 is a perspective view of a ceramic heater 1 according to a first embodiment of the present disclosure, and FIG. 2 is an exploded perspective view of the ceramic heater 1 according to the first embodiment. FIG. 3 to FIG. 8 are a plan view, a bottom view, a front view, a rear view, a right side view, and a left side view, respectively, of the ceramic heater 1 according to the first embodiment. The rear view, the right side view, and the left side view are represented in the same manner as in the front view. FIG. 9 is an enlarged sectional view for illustrating a part of the ceramic heater 1 according to the first embodiment when cut along a vertical plane including the line A-A in FIG. 4. FIG. 10 is a sectional view for illustrating a schematic configuration with the ceramic heater 1 according to the first embodiment being used in a semiconductor manufacturing apparatus. FIG. 11 is a bottom view of a plate, which is a constituent member of the ceramic heater 1 according to the first embodiment. FIG. 12 and FIG. 13 are a plan view and a front view, respectively, of an auxiliary member, which is a constituent member of the ceramic heater 1 according to the first embodiment.

The ceramic heater 1 is installed inside a vacuum chamber, for example, at the time of performing processing, such as chemical vapor deposition (CVD) or etching, on the wafer in a semiconductor manufacturing apparatus, and is used for heating a wafer so that a temperature of the wafer becomes a desired temperature. The inside of the vacuum chamber is set to have a vacuum atmosphere or a reduced-pressure atmosphere, and processing, such as forming a thin film on the wafer or performing etching using plasma, is performed inside the vacuum chamber.

Referring to FIG. 2, the ceramic heater 1 includes: a plate 2 having a plate shape; a shaft 3 having a cylindrical shape; and an auxiliary member 4 having a plate shape. The plate 2, the shaft 3, and the auxiliary member 4 are integrated by the plate 2 and the auxiliary member 4 being joined to each other by, for example, diffusion joining, and the shaft 3 and the auxiliary member 4 being joined to each other by, for example, diffusion joining.

### Description of Plate

Referring to FIG. 1 to FIG. 8, the plate 2 is formed in a plate shape having a pair of main surfaces spaced apart from each other in a thickness direction, that is, a first main surface 20 and a second main surface 21. The first main surface 20 is formed as a surface on which a wafer is to be placed. The plate 2 may be formed of, for example, a disc having a circular shape in plan view. The size of the plate 2 is, for example, a diameter of about 300 mm or more and about 330 mm or less, and a thickness of about 20 mm. The term “plan view” as used in the present disclosure refers to viewing from a direction perpendicular to the first main surface 20 or the second main surface 21.

Referring to FIG. 9, a resistance heating element 5, which generates heat through energization, is built into the plate 2. The resistance heating element 5 may be formed of a coil containing, for example, molybdenum or tungsten as a main component. The resistance heating element 5 is embedded in substantially the entire area between the first main surface 20 and the second main surface 21 of the plate 2, along a plane parallel to the first main surface 20 and the second main surface 21. Accordingly, the entirety of the plate 2 is heated by the resistance heating element 5, and the wafer placed on the first main surface 20 is heated. The resistance heating element 5 may be divided into, for example, a first resistance heating element arranged in an area near the center of the plate 2, and a second resistance heating element arranged in an area near an outer periphery of the plate 2. In this case, as illustrated in FIG. 10, a pair of first power feeding rods 17 made of a metal and to be connected to a pair of terminals 12 at both ends of the first resistance heating element, respectively, and a pair of second power feeding rods 18 made of a metal and to be connected to a pair of terminals 13 at both ends of the second resistance heating element, respectively, are attached to the plate 2.

Referring to FIG. 2, FIG. 4, FIG. 9, and FIG. 11, the plate 2 has a recess portion 22 into which the auxiliary member 4 is allowed to be fitted. The recess portion 22 is formed in the second main surface 21 of the plate 2 so as to be recessed from the second main surface 21 toward the first main surface 20. The recess portion 22 includes a first recess portion 23, into which a lid portion 40 of the auxiliary member 4 is allowed to be fitted, and a second recess portion 24, into which a connecting portion 41 of the auxiliary member 4 is allowed to be fitted. The first recess portion 23 and the second recess portion 24 are continuous with each other.

The shape of the second recess portion 24 in plan view is an annular shape so as to correspond to a shape of the connecting portion 41 of the auxiliary member 4, and is a circular annular shape in this embodiment. The second recess portion 24 is formed so as to include: a bottom surface 242 having an annular shape, against which the connecting portion 41 having an annular shape is allowed to abut; an outer peripheral surface 240 that faces an outer peripheral surface 410 of the connecting portion 41; and an inner peripheral surface 241 that faces an inner peripheral surface 411 of the connecting portion 41. The center of the second recess portion 24 in plan view matches the center of the second main surface 21, and the second recess portion 24 is formed in the second main surface 21 so as to be concentric with the second main surface 21. A protrusion 25 having a flat columnar shape and surrounded by the second recess portion 24 is formed at the center on the second main surface 21 side of the plate 2, along with the formation of the second recess portion 24.

The first recess portion 23 is formed in the second main surface 21 so as to extend linearly from the second recess portion 24 toward an outer periphery of the second main surface 21. Out of a start end 230 and a terminal end 231, which are both ends of the first recess portion 23, the start end 230 is connected to the second recess portion 24, and the terminal end 231 is located closer to the outer periphery of the second main surface 21.

Referring to FIG. 2, FIG. 9, and FIG. 11, the plate 2 has a groove 26 serving as a thermocouple passage through which a thermocouple is allowed to pass. The groove 26 is formed in the plate 2 so as to be recessed from the second main surface 21 toward the first main surface 20. Further, the groove 26 extends from an area on an inner side of the shaft 3 to an area on an outer side of the shaft 3, and toward the outer periphery of the second main surface 21, on the second main surface 21 side of the plate 2. That is, out of a start end 260 and a terminal end 261, which are both ends of the groove 26, the start end 260 is located on the inner side of the shaft 3. The terminal end 261 is located on the outer side of the shaft 3, and is located closer to the terminal end 231 of the first recess portion 23. In this embodiment, the groove 26 extends to a position closer to the outer periphery of the second main surface 21, and the terminal end 261 of the groove 26 is located closer to the outer periphery of the second main surface 21. However, the terminal end 261 of the groove 26 may be located away from the outer periphery of the second main surface 21, as long as the terminal end 261 is located on the outer side of the shaft 3. The position of the terminal end 231 of the first recess portion 23 is changed according to the position of the terminal end 261 of the groove 26.

In this embodiment, the groove 26 includes: a first groove portion 27 formed in a bottom surface 220 of the recess portion 22 (a bottom surface 233 of the first recess portion 23 and the bottom surface 242 of the second recess portion 24) so as to be recessed toward the first main surface 20; and a second groove portion 28 formed in the second main surface 21 of the plate 2 (a front surface of the protrusion 25) so as to be recessed toward the first main surface 20. The second groove portion 28 is in communication with the first groove portion 27. As illustrated in FIG. 11, the first groove portion 27 includes an outer portion 262, which is a portion of the groove 26 located near the outer periphery of the second main surface 21 and on the outer side of the shaft 3, and a part of an inner portion 263, which is a portion of the groove 26 located near the center of the second main surface 21 and on the inner side of the shaft 3. The second groove portion 28 includes the remaining part of the inner portion 263 of the groove 26. A thermocouple is inserted from the second groove portion 28 of the groove 26, and is then caused to pass through the first groove portion 27, to thereby be inserted to the vicinity of the outer periphery of the plate 2.

Referring to FIG. 10, a first thermocouple 14 for detecting a temperature near the outer periphery of the plate 2, and a second thermocouple 15 for detecting a temperature near the center of the plate 2 are attached to the plate 2 in order to confirm that the entirety of the plate 2 is at a uniform temperature due to the resistance heating element 5. The first thermocouple 14 is formed using, for example, a sheathed thermocouple. The first thermocouple 14 is caused to pass through the groove 26 of the plate 2 so that a temperature measurement portion at a distal end of the first thermocouple 14 is positioned near the outer periphery of the plate 2. Accordingly, the temperature near the outer periphery of the plate 2 is detected by the first thermocouple 14. The second thermocouple 15 is inserted into a recess 29 formed in an area on the inner side of the shaft 3 in the second main surface 21 of the plate 2 so that a temperature measurement portion at the distal end of the second thermocouple 15 is positioned near the center of the plate 2. Accordingly, the temperature near the center of the plate 2 is detected by the second thermocouple 15.

Referring to FIG. 10, an electrode 6 containing molybdenum, tungsten, or the like as a main component, such as an electrostatic electrode for wafer chucking or a radio frequency (RF) electrode for plasma generation, may be built into the plate 2. In this case, a third power feeding rod 19 made of a metal and to be connected to a terminal 16 of the electrode 6 is attached to the plate 2.

### Description of Shaft

Referring to FIG. 2 and FIG. 4 to FIG. 8, the shaft 3 is formed in a cylindrical shape having a pair of openings respectively located at both ends in an axial direction, that is, a first opening 30 and a second opening 31. The shaft 3 supports the plate 2 on the side of the second main surface 21 (the surface opposite to the first main surface 20, on which the wafer is to be placed). The shaft 3 may be formed of, for example, a cylinder in which a shape of a transverse section of the cylinder when cut along a plane orthogonal to the axial direction is circular. A diameter of the shaft 3 is smaller than the diameter of the plate 2.

In the shaft 3, a distal end portion 32, which is a portion surrounding the first opening 30, and a base end portion 33, which is a portion surrounding the second opening 31, may be formed of, for example, flanges. The distal end portion 32 of the shaft 3 is joined to the plate 2 via the auxiliary member 4 arranged between the plate 2 and the shaft 3. As illustrated in FIG. 10, the base end portion 33 of the shaft 3 is connected to a support base 7 via an O-ring 8. Accordingly, an internal space of the shaft 3 is blocked from a space inside the vacuum chamber of the semiconductor manufacturing apparatus, which is an external space.

Referring to FIG. 10, the inside of the shaft 3 accommodates the first thermocouple 14 and the second thermocouple 15, in addition to the first power feeding rods 17 and the second power feeding rods 18 connected to the resistance heating element 5, and the third power feeding rod 19 connected to the electrode 6. Accordingly, those metal members, such as the power feeding rods and the thermocouples, are isolated from the space inside the vacuum chamber of the semiconductor manufacturing apparatus, which is the external space, and hence are prevented from being exposed to plasma or the like. Although not particularly limited, the first thermocouple 14 is preferably caused to pass through the inside of a thermocouple guide having a cylindrical shape, and then through the groove 26 of the plate 2. The thermocouple guide includes a straight portion extending in the axial direction (vertical direction) inside the shaft 3, and a curved portion at which a direction in which the thermocouple guide extends is changed from the vertical direction to a horizontal direction. The thermocouple guide is arranged so that the curved portion is inserted into the second groove portion of the groove 26, and an outlet of the curved portion faces an inlet of the first groove portion 27 of the groove 26. Accordingly, the first thermocouple 14 can be smoothly inserted into the groove 26 of the plate 2 with use of the thermocouple guide.

Referring to FIG. 2 and FIG. 4 to FIG. 8, a shaft portion between the distal end portion 32 and the base end portion 33 of the shaft 3 may have a shape in which an inner diameter and an outer diameter do not change along the axial direction. Alternatively, the shaft portion of the shaft 3 may have a shape that includes a small diameter portion 34 near the base end portion 33, and a large diameter portion 35 having an inner diameter and an outer diameter that are larger than those of the small diameter portion 34 near the distal end portion 32, as in this embodiment.

### Description of Auxiliary Member

Referring to FIG. 2, FIG. 4, FIG. 9, FIG. 12, and FIG. 13, the auxiliary member 4 is formed in a plate shape (including a rod shape) in which, for example, a thickness of the lid portion 40 is 1.0 mm or more and 7.5 mm or less, and a thickness of the connecting portion 41 is 4.0 mm or more and 10.5 mm or less. The auxiliary member 4 is joined to the plate 2. The auxiliary member 4 includes the lid portion 40 and the connecting portion 41. The auxiliary member 4 is arranged between the plate 2 and the shaft 3, the connecting portion 41 is sandwiched between the plate 2 and the shaft 3, and the distal end portion 32 of the shaft 3 is joined to the connecting portion 41.

The lid portion 40 extends along the outer portion 262 that is a portion, which is located on the outer side of the shaft 3, of the groove 26 formed in the plate 2. The lid portion 40 is joined to the plate 2 so as to cover the outer portion 262 of the groove 26. The lid portion 40 may be formed of, for example, an elongated flat plate extending linearly and having a length sufficiently larger than its width. The width of the lid portion 40 is larger than the width of the groove 26. The length of the lid portion 40 is larger than the length of the outer portion 262 of the groove 26. When the outer portion 262 of the groove 26 is covered with the lid portion 40, and the inner portion 263 of the groove 26 located near the center of the plate 2 is located on the inner side of the shaft 3, an internal space of the groove 26 is blocked from the space inside the vacuum chamber of the semiconductor manufacturing apparatus, which is an external space of the groove 26. Accordingly, the temperature near the outer periphery of the plate 2 can be detected with high accuracy by the first thermocouple 14.

When the connecting portion 41 is joined to the plate 2, and the distal end portion 32 of the shaft 3 is joined to the connecting portion 41, the plate 2 and the shaft 3 are connected to each other to be integrated. The shape and size of an outer periphery of the connecting portion 41 in plan view are not particularly limited, but preferably match the shape and size of an outer periphery of the distal end portion 32 of the shaft 3 to be joined to the connecting portion 41. In this embodiment, the shape of the connecting portion 41 in plan view is an annular shape so as to correspond to the shape of the distal end portion 32 of the shaft 3. The shape and size of an inner periphery of the connecting portion 41 in plan view are also not particularly limited, but preferably match the shape and size of an inner periphery of the distal end portion 32 of the shaft 3. The connecting portion 41 may be formed of, for example, a ring plate having a circular annular shape so as to correspond to the shape of the distal end portion 32 of the shaft 3. Accordingly, the distal end portion 32 of the shaft 3 abuts against the connecting portion 41. Referring to FIG. 10, the connecting portion 41 of the auxiliary member 4 is sandwiched between the plate 2 and the distal end portion 32 of the shaft 3. Under this state, when the distal end portion 32 of the shaft 3 is pressed against the plate 2, the distal end portion 32 of the shaft 3 and the connecting portion 41 are joined to each other, and simultaneously the connecting portion 41 and the plate 2 are joined to each other. With the abutment of the distal end portion 32 of the shaft 3 against the connecting portion 41, the distal end portion 32 of the shaft 3 can be uniformly joined to the connecting portion 41, and the connecting portion 41 can be uniformly joined to the plate 2.

Referring to FIG. 2, FIG. 4, and FIG. 9, the auxiliary member 4 is fitted into the recess portion 22 formed in the plate 2 in this embodiment. The lid portion 40 of the auxiliary member 4 is fitted into the first recess portion 23 of the recess portion 22, and the connecting portion 41 of the auxiliary member 4 is fitted into the second recess portion 24 of the recess portion 22. Accordingly, positioning of the auxiliary member 4 relative to the plate 2 is facilitated, and accordingly, positioning of the shaft 3 relative to the plate 2 is facilitated. Although not particularly limited, a front surface of the lid portion 40 is preferably flush with the second main surface 21 of the plate 2. A front surface of the connecting portion 41 may protrude from the second main surface 21 of the plate 2, or may be flush with the second main surface 21 of the plate 2.

The front surface of the lid portion 40 refers to a second surface 402 opposite to a first surface 401, which is allowed to abut against the plate 2, of the lid portion 40. The front surface of the connecting portion 41 refers to a second surface 413 that is opposite to a first surface 412, which is allowed to abut against the plate 2, of the connecting portion 41, and that is allowed to abut against the distal end portion 32 of the shaft 3. The lid portion 40 includes: the first surface 401 and the second surface 402 spaced apart from each other in the thickness direction; and side surfaces 400 located between the first surface 401 and the second surface 402. The connecting portion 41 includes: the first surface 412 and the second surface 413 spaced apart from each other in the thickness direction; an outer side surface 410 that is located between the first surface 412 and the second surface 413, and is the outer peripheral surface of the connecting portion 41; and an inner side surface 411 that is located between the first surface 412 and the second surface 413, is on the radially inner side of the outer side surface 410, and is the inner peripheral surface of the connecting portion 41.

The width of the lid portion 40 is not particularly limited, but is preferably smaller than the width of the first recess portion 23. The length of the lid portion 40 is not particularly limited, but is preferably smaller than the length of the first recess portion 23. The outer diameter of the connecting portion 41 is not particularly limited, but is preferably smaller than the outer diameter of the second recess portion 24. Accordingly, a gap G is defined between the side surface of the auxiliary member 4 and the side surface of the recess portion 22. The side surface of the auxiliary member 4 refers to the side surfaces 400 of the lid portion 40 (surfaces excluding the second surface 402, which is the front surface of the lid portion 40, and the first surface 401, which is the rear surface), and the outer side surface 410, which is the outer peripheral surface of the connecting portion 41. The side surface of the recess portion 22 refers to side surfaces 232 of the first recess portion 23 (surfaces excluding the bottom surface 220), and the outer side surface 240, which is the outer peripheral surface of the second recess portion 24.

In addition, the inner diameter of the connecting portion 41 is not particularly limited, but is preferably larger than the inner diameter of the second recess portion 24 (the diameter of the protrusion 25). Accordingly, a gap G is defined between the inner peripheral surface 411 of the connecting portion 41 and the inner peripheral surface of the recess portion 22. The inner peripheral surface of the recess portion 22 refers to an inner side surface (a peripheral surface of the protrusion 25) 241, which is the inner peripheral surface of the second recess portion 24.

Each of those gaps G is, for example, 300 μm or more and 700 μm or less. With the formation of the gap G in at least one of a portion between the side surface of the auxiliary member 4 and the side surface of the recess portion 22 or a portion between the inner peripheral surface 411 of the connecting portion 41 and the inner peripheral surface 241 of the recess portion 22, lateral heat conduction between the plate 2 and the auxiliary member 4 can be suppressed. Accordingly, heat of the plate 2 hardly transfers to the shaft 3 via the auxiliary member 4, resulting in that the temperature uniformity of the first main surface 20, on which the wafer is to be placed, can be improved.

The gap G may be formed only in a portion between the side surface of the auxiliary member 4 and the side surface of the recess portion 22, and a portion between the inner peripheral surface 411 of the connecting portion 41 and the inner peripheral surface 241 of the recess portion 22. However, the formation of the gap G over the entire periphery is preferred because lateral heat conduction between the plate 2 and the auxiliary member 4 can be more satisfactorily suppressed. The presence of the gap G enables distinction between the plate 2 and the auxiliary member 4.

### Description of Material for Ceramic Heater

The plate 2, the shaft 3, and the auxiliary member 4 that form the ceramic heater 1 are formed of a sintered body of ceramics, such as aluminum nitride, aluminum oxide, silicon carbide, or silicon nitride. Each of the constituent members 2 to 4 of the ceramic heater 1 preferably contains, as a main component, aluminum nitride, which has high thermal conductivity, among the components described above. Accordingly, the thermal conductivity of the plate 2 can be improved. The term “main component” means that each of the constituent members 2 to 4 of the ceramic heater 1 contains aluminum nitride at 95 mass % or more, preferably 99 mass % or more.

Although not particularly limited, the plate 2 and the shaft 3 may each contain aluminum nitride as a main component, and an oxide of a rare earth element (hereinafter referred to as “rare earth oxide”), an oxide of an alkaline earth element, or an oxide of a transition metal element. Examples of the rare earth oxide include yttria (yttrium oxide), cerium oxide, and samarium oxide. Among those, yttria is preferred. Examples of the oxide of the alkaline earth element include magnesia (magnesium oxide), and examples of the oxide of the transition metal element include titania (titanium oxide). In this case, the thermal conductivity of aluminum nitride is improved by the addition of yttria. Accordingly, when the plate 2 containing aluminum nitride as a main component contains yttria, the thermal conductivity of the plate 2 can be improved. The content of yttria in the plate 2 and the shaft 3 is not particularly limited, but is preferably 0.05 mass % or more. The plate 2 and the shaft 3 exhibit a gray color when containing, for example, aluminum nitride as a main component and containing yttria.

Although not particularly limited, it is preferred that the auxiliary member 4 contain aluminum nitride as a main component, and contain no rare earth oxide, such as yttria. The phrase “the auxiliary member 4 containing no rare earth oxide” as used herein means that the content of the rare earth oxide in the auxiliary member 4 is equal to or less than the detection limit, and does not exclude the auxiliary member 4 containing a trace amount of the rare earth oxide. The phrase “being equal to or less than the detection limit” means that, for example, the content of the rare earth oxide in the auxiliary member 4 is 5 mass ppm or less when measured by inductively coupled plasma atomic emission spectroscopy (ICP-AES).

The auxiliary member 4 may contain an oxide of at least one of an oxide of an alkaline earth element or an oxide of a transition metal element. Examples of the oxide of the alkaline earth element include magnesia, and examples of the oxide of the transition metal element include titania. The content of the oxide in the auxiliary member 4 is, for example, 0.1 mass % or more and 3.0 mass % or less. When the auxiliary member 4 contains, for example, aluminum nitride as a main component and contains no yttria, the auxiliary member 4 exhibits a gray color different in shade from the case of containing yttria. Further, when the auxiliary member 4 contains, for example, aluminum nitride as a main component, contains no yttria, and contains magnesia and titania, the auxiliary member 4 exhibits a dark gray color. Accordingly, the auxiliary member 4 has a difference in color shade in appearance from the plate 2 and the shaft 3 that contain yttria. Thus, the plate 2 and the shaft 3 can be distinguished from the auxiliary member 4 by the color shade.

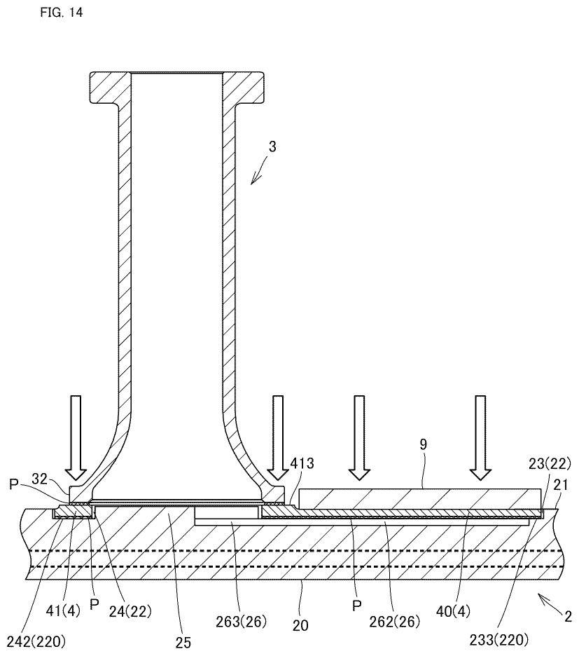

The plate 2, the shaft 3, and the auxiliary member 4 are integrated by, for example, diffusion joining using a flux P illustrated in FIG. 14. Examples of the flux P include a paste containing calcia, alumina, and yttria. With the auxiliary member 4 containing no rare earth oxide such as yttria, diffusion of a rare earth component of the flux P is promoted near the joining interface between the auxiliary member 4 and the plate 2 and near the joining interface between the auxiliary member 4 and the shaft 3 at the time of joining of the plate 2 and the auxiliary member 4 and joining of the shaft 3 and the auxiliary member 4. Accordingly, joining of the plate 2 and the auxiliary member 4 and joining of the shaft 3 and the auxiliary member 4 can be performed at a low temperature and with a low load.

Further, the auxiliary member 4 containing no yttria has thermal conductivity lower than that of the plate 2 containing yttria, but the auxiliary member 4 is attached only to a part of the second main surface 21 of the plate 2. Accordingly, the time required for making the temperature of the entire plate 2 including the auxiliary member 4 uniform is shortened, as compared to a case in which the auxiliary member 4 is attached to the entire area of the second main surface 21 of the plate 2. In the process of manufacturing a semiconductor, it is required to set the temperature of the plate 2 to a target temperature by raising or lowering the temperature of the plate 2, but the temperature of the plate 2 can be quickly set to the target temperature so that the operation of the semiconductor manufacturing apparatus is stabilized.

### Description of Method of Manufacturing Ceramic Heater

Next, an outline of a method of manufacturing the ceramic heater 1 according to this embodiment is described with reference to FIG. 14. First, the plate 2, the shaft 3, and the auxiliary member 4 are manufactured. The plate 2, the shaft 3, and the auxiliary member 4 are obtained by manufacturing ceramic molded bodies by, for example, a mold cast method, and firing the ceramic molded bodies. The term “mold cast method” as used herein refers to a method of obtaining a molded body by injecting a ceramic slurry containing ceramic raw material powder and a molding agent into a mold, and chemically reacting the molding agent in the mold to mold the ceramic slurry. The connecting portion 41 of the auxiliary member 4 may be formed into a ring plate and then fired, or may be formed into a disc and then fired, and after that, the center of the disc may be hollowed out by machining to form a ring plate.

Then, the recess portion 22 is formed in the second main surface 21 of the plate 2, and then the groove 26 is formed. The recess portion 22 and the groove 26 can be formed by, for example, cutting or blasting.

Then, the plate 2 is placed on a work table so that the second main surface 21 faces upward. After that, the flux P is applied to a portion, at which the auxiliary member 4 is to be installed, on the second main surface 21 side of the plate 2, which is the bottom surface 220 of the recess portion 22 in this embodiment.

Then, the auxiliary member 4 is fitted into the recess portion 22 of the plate 2 to install the auxiliary member 4 onto the plate 2. At this time, the outer portion 262, which is located near the outer periphery of the second main surface 21, of the groove 26 formed in the plate 2 is covered with the lid portion 40 of the auxiliary member 4, and the inner portion 263, which is located near the center of the second main surface 21, of the groove 26 is located on an inner side of the connecting portion 41.

Then, the flux P is applied to the second surface 413, which is the front surface of the connecting portion 41 of the auxiliary member 4. After that, the shaft 3 is installed onto the auxiliary member 4 so that the distal end portion 32 faces downward so as to cover the connecting portion 41.

Finally, joining of the shaft 3 and the connecting portion 41 of the auxiliary member 4, and joining of the connecting portion 41 of the auxiliary member 4 and the plate 2 are simultaneously performed while a load of about 10 kg/cm² or more and about 40 kg/cm² or less is being applied to the shaft 3 from above, for example, under a nitrogen atmosphere and at a temperature of about 1,600° C. or more and about 1,700° C. or less. Simultaneously, joining of the lid portion 40 of the auxiliary member 4 and the plate 2 is performed while a load of the same surface pressure is being applied to the lid portion 40 of the auxiliary member 4 from above by a pressing member 9. Thus, the plate 2, the shaft 3, and the auxiliary member 4 are integrated to manufacture the ceramic heater 1.

For the ceramic heater 1, through holes are formed in the second main surface 21 of the plate 2 at positions corresponding to the terminals 12, 13, and 16. Accordingly, the terminals 12, 13, and 16 are exposed, and the corresponding power feeding rods 17, 18, and 19 can be connected to the terminals 12, 13, and 16. Further, the recess 29 into which a second thermocouple 15 is allowed to be inserted is formed in the second main surface 21 of the plate 2.

As described above, in the method of manufacturing the ceramic heater 1 according to this embodiment, the connecting portion 41 of the auxiliary member 4 is pressed against the plate 2 by the distal end portion 32 of the shaft 3, and at the same time, the lid portion 40 of the auxiliary member 4 is pressed against the plate 2 by the pressing member 9, so that the plate 2, the auxiliary member 4, and the shaft 3 are joined to each other with single pressing. Accordingly, with the method of manufacturing the ceramic heater 1 according to this embodiment, the plate 2, the auxiliary member 4, and the shaft 3 can be easily integrated, and the manufacturing cost of the ceramic heater 1 can be reduced.

In addition, joining of the plate 2, the auxiliary member 4, and the shaft 3 is performed in a heated state with heat applied. The resistance heating element 5 built into the plate 2 contains, for example, molybdenum as a main component, and hence the electric resistance of the resistance heating element 5 changes due to carbonization or the like when the resistance heating element 5 is heated. Accordingly, in order to uniformly heat the plate 2 by the resistance heating element 5, it is desirable to suppress a change in the electric resistance of the resistance heating element 5. With the plate 2, the auxiliary member 4, and the shaft 3 being able to be joined to each other with single pressing as in the method of manufacturing the ceramic heater 1 according to this embodiment, variations in the electric resistance of the resistance heating element 5 can be suppressed. Thus, with the method of manufacturing the ceramic heater 1 according to this embodiment, the temperature uniformity of the plate 2 can be improved.

### Description of Operation and Effect of Ceramic Heater

In the ceramic heater 1 according to the first embodiment, no cavity is formed in the plate 2 as a thermocouple passage for inserting the first thermocouple 14 into the plate 2, but instead thereof, a groove 26 is formed so as to be recessed from the second main surface 21 toward the first main surface 20 of the plate 2. The outer portion 262 of the groove 26 is covered with the lid portion 40 of the auxiliary member 4 joined to the plate 2 so that the internal space is blocked from the external space. The inner portion 263 of the groove 26 is surrounded by the connecting portion 41 of the auxiliary member 4 joined to the plate 2, and the shaft 3 is joined to the connecting portion 41 of the auxiliary member 4 so that the internal space is blocked from the external space. Accordingly, the first thermocouple 14 inserted into the groove 26 is isolated from the external space so that the temperature near the outer periphery of the plate 2 is detected with high accuracy by the first thermocouple 14.

Further, in the ceramic heater 1 according to the first embodiment, even when a load is applied to the auxiliary member 4 and the plate 2 at the time when the auxiliary member 4 and the shaft 3 are joined to the plate 2, bending hardly occurs in a part of each of the auxiliary member 4 and the plate 2. Accordingly, occurrence of, for example, crushing of the groove 26 serving as the thermocouple passage or fracture of the plate 2 is prevented at the time of joining of the plate 2 and the shaft 3.

Further, in the ceramic heater 1 according to the first embodiment, the shaft 3 is joined to the connecting portion 41 of the auxiliary member 4, and the connecting portion 41 is joined to the plate 2, so that the shaft 3 is indirectly joined to the plate 2 with the connecting portion 41 sandwiched therebetween. With the auxiliary member 4 being arranged between the plate 2 and the shaft 3 as described above, the joining interface between the plate 2 and the shaft 3 increases as compared to a case in which the shaft 3 is directly joined to the plate 2. The joining interface may become an obstacle to heat conduction, and hence heat removal from the plate 2 to the shaft 3 is reduced due to the increase in the joining interface. Accordingly, temperature unevenness of the plate 2 can be suppressed, resulting in that the temperature uniformity of the plate 2 can be improved. In addition, only the auxiliary member 4 is attached to the plate, that is, the number of members attached to the plate 2 is small, and hence the temperature unevenness of the plate 2 can be suppressed, resulting in that the temperature uniformity of the plate 2 can be improved.

### Second Embodiment

Next, a ceramic heater 10 according to a second embodiment of the present disclosure is described. The ceramic heater 10 according to the second embodiment basically has the same structure and the same effects as in the ceramic heater 1 according to the first embodiment. However, the second embodiment is different from the first embodiment in the method of attaching the auxiliary member 4 to the plate 2. Differences from the first embodiment are mainly described below.

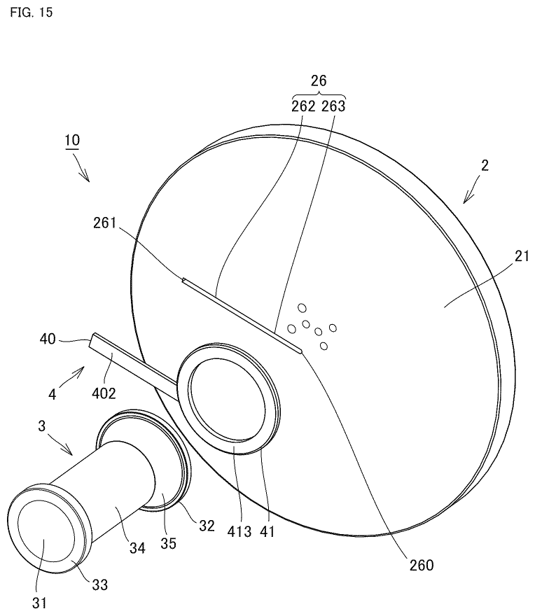

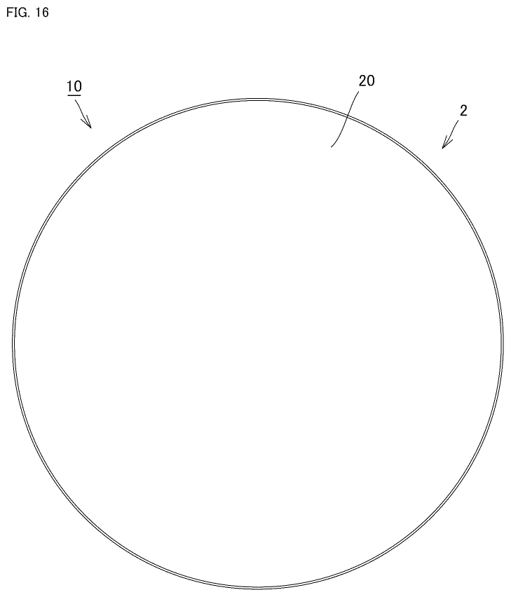

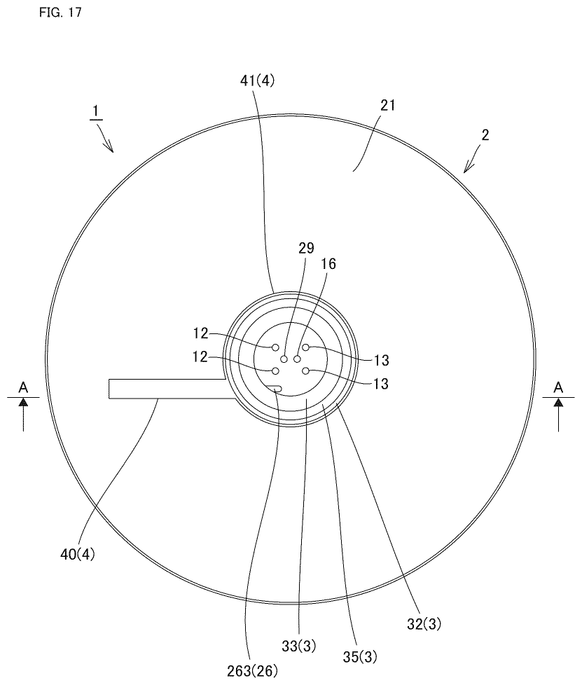

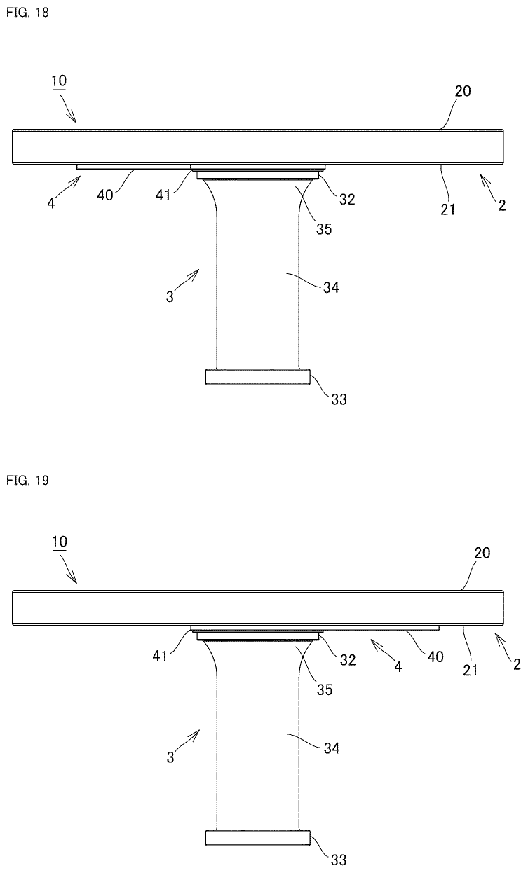

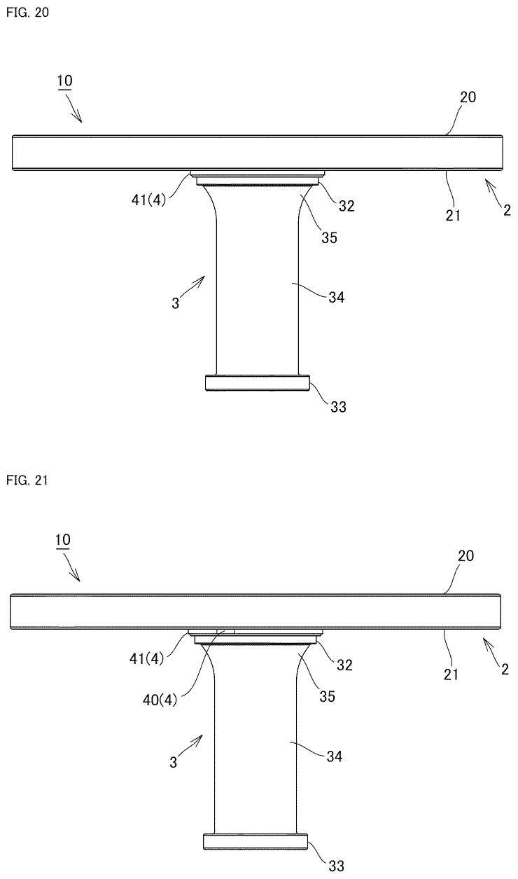

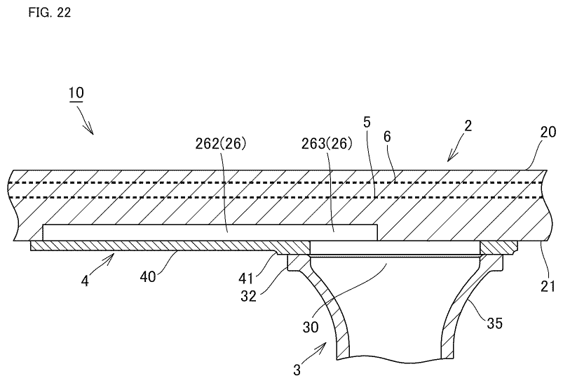

FIG. 15 is an exploded perspective view of the ceramic heater 10 according to the second embodiment. FIG. 16 to FIG. 21 are a plan view, a bottom view, a front view, a rear view, a right side view, and a left side view, respectively, of the ceramic heater 10 according to the second embodiment. FIG. 22 is an enlarged sectional view for illustrating a part of the ceramic heater 10 according to the second embodiment when cut along a vertical plane including the line A-A in FIG. 17.

In the ceramic heater 1 according to the first embodiment described above, the recess portion 22 is formed in the plate 2, and the auxiliary member 4 is joined to the plate 2 while being fitted into the recess portion 22. In contrast, in the ceramic heater 10 according to the second embodiment, no recess portion 22 is formed in the plate 2, and the auxiliary member 4 is joined to the plate 2 while being placed on the second main surface 21.

The groove 26 is formed in the second main surface 21 of the plate 2 so as to be recessed toward the first main surface 20. Further, the groove 26 extends from the inner area of the shaft 3 to the outer area of the shaft 3 and up to the position closer to the outer periphery of the second main surface 21, in the second main surface 21 of the plate 2. That is, out of the start end 260 and the terminal end 261, which are both ends of the groove 26, the start end 260 is located on the inner side of the shaft 3. The terminal end 261 is located on the outer side of the shaft 3, and is located closer to the outer periphery of the second main surface 21. The first thermocouple 14 is inserted from the inner portion 263 of the groove 26 located on the inner side of the shaft 3, and is then caused to pass through the outer portion 262 of the groove 26 located on the outer side of the shaft 3, to thereby be inserted to the vicinity of the outer periphery of the plate 2. In this embodiment, the groove 26 extends up to the position closer to the outer periphery of the second main surface 21, and the terminal end 261 of the groove 26 is located closer to the outer periphery of the second main surface 21, but the terminal end 261 of the groove 26 may be located away from the outer periphery of the second main surface 21 as long as the terminal end 261 is located on the outer side of the shaft 3.

The auxiliary member 4 is joined to the second main surface 21 of the plate 2 so that the outer portion 262 of the groove 26 is covered with the lid portion 40, and the inner portion 263 of the groove 26 is located on the inner side of the connecting portion 41. Then, the distal end portion 32 of the shaft 3 is joined to the connecting portion 41 of the auxiliary member 4, so that the plate 2, the auxiliary member 4, and the shaft 3 are integrated.

### Third Embodiment

Next, a ceramic heater 11 according to a third embodiment of the present disclosure is described. The ceramic heater 11 according to the third embodiment basically has the same structure and the same effects as in the ceramic heater 1 according to the first embodiment. However, the third embodiment is different from the first embodiment in the shape of the recess portion 22 formed in the plate 2 for fitting the auxiliary member 4 into the recess portion 22. Differences from the first embodiment are mainly described below.

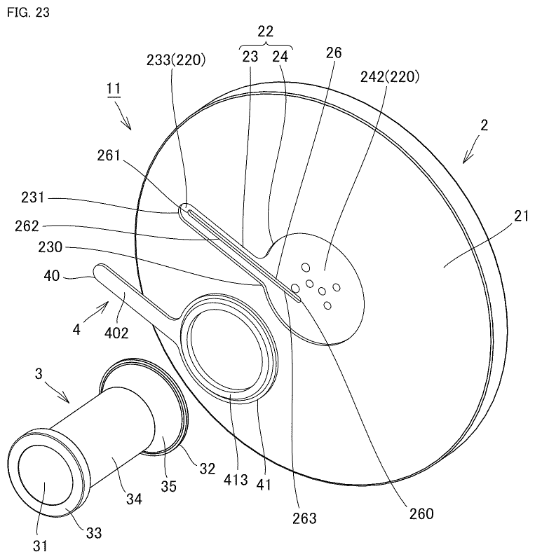

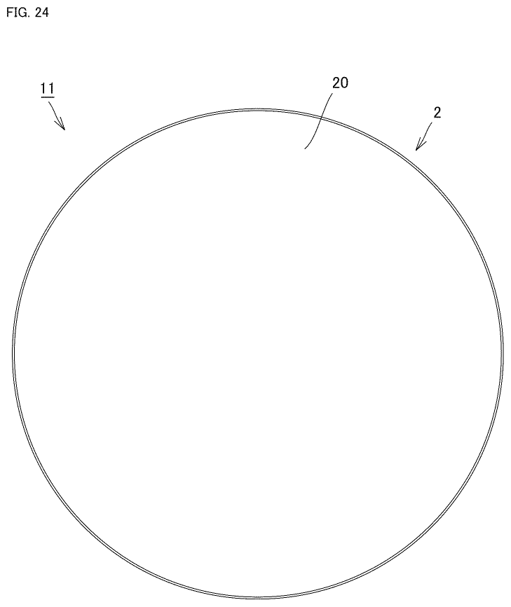

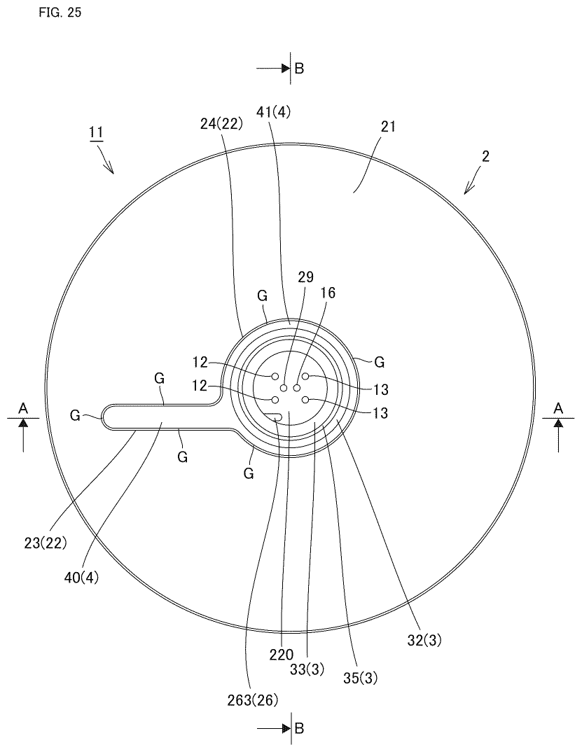

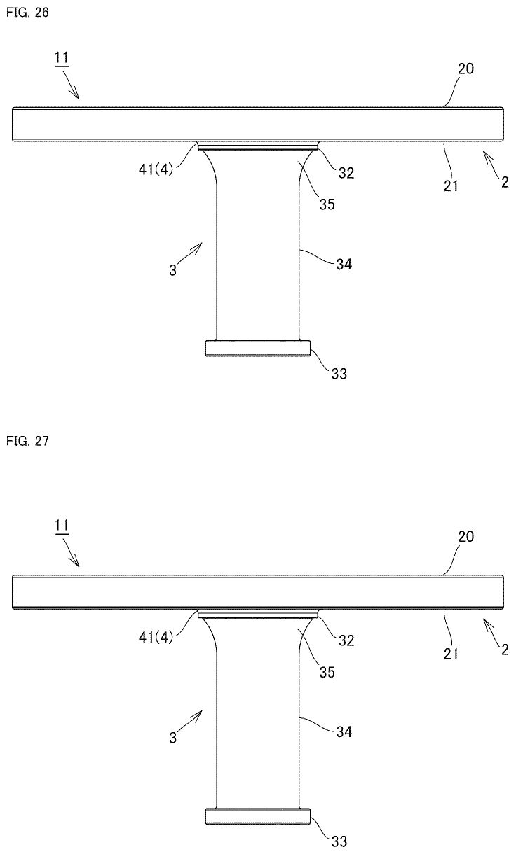

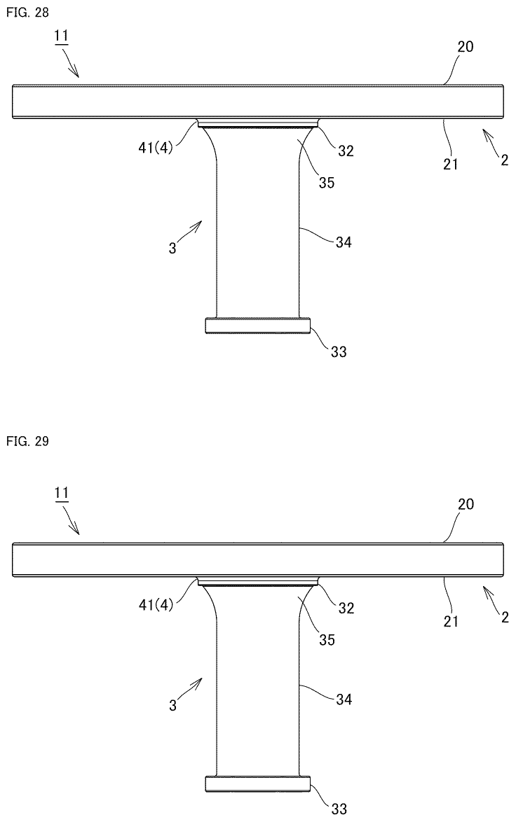

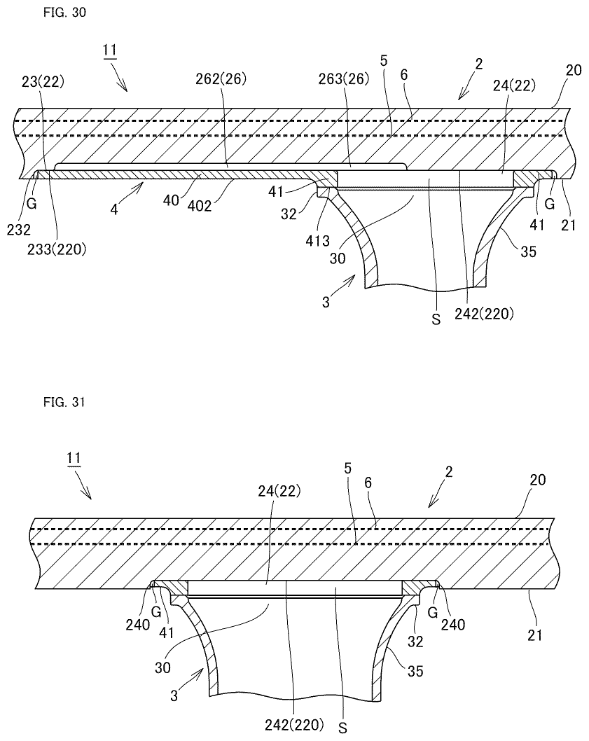

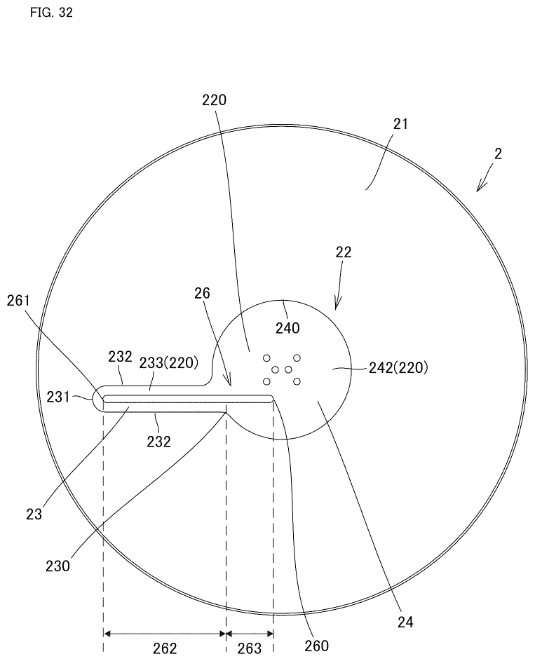

FIG. 23 to FIG. 29 are an exploded perspective view, a plan view, a bottom view, a front view, a rear view, a right side view, and a left side view, respectively, of the ceramic heater 11 according to the third embodiment. FIG. 30 and FIG. 31 are enlarged sectional views for illustrating a part of the ceramic heater 11 according to the third embodiment. FIG. 32 is a bottom view of the plate 2, which is a constituent member of the ceramic heater 11 according to the third embodiment.

In the ceramic heater 1 according to the first embodiment described above, the second recess portion 24 having an annular shape is formed in the plate 2, and the connecting portion 41 having an annular shape of the auxiliary member 4 is fitted into the second recess portion 24 so that the protrusion 25 is fitted into the inner side of the connecting portion 41. Meanwhile, in the ceramic heater 11 according to the third embodiment, the second recess portion 24 formed in the plate 2 so as to be continuous with the first recess portion 23 has a shallow bowl shape, and has a shape formed by hollowing out a solid thin plate from the second main surface 21 side of the plate 2. In this embodiment, the shape of the second recess portion 24 in plan view is a circular shape so as to correspond to the outer shape of the connecting portion 41 of the auxiliary member 4, and the second recess portion 24 has a shape formed by hollowing out a thin disc from the second main surface 21 side of the plate 2. The second recess portion 24 is formed so as to include a bottom surface 242 having a flat circular shape, against which the connecting portion 41 having an annular shape is allowed to abut, and an outer peripheral surface 240 that faces the outer peripheral surface 410 of the connecting portion 41. The center of the second recess portion 24 in plan view matches the center of the second main surface 21, and the second recess portion 24 is formed in the plate 2 so as to be concentric with the second main surface 21.

Referring to FIG. 31, a corner between the outer peripheral surface 240 and the bottom surface 242 in the second recess portion 24 may be chamfered. The chamfering may be C-chamfering or R-chamfering. The term “C-chamfering” refers to a case in which the corner between the outer peripheral surface 240 and the bottom surface 242 is cut obliquely at a predetermined angle (for example, 45°). Further, the term “R-chamfering” refers to a case in which the corner between the outer peripheral surface 240 and the bottom surface 242 is smoothly cut to be rounded. The roundness inevitably formed at the corner between the outer peripheral surface 240 and the bottom surface 242 at the time of forming the second recess portion 24 in the plate 2 does not correspond to chamfering. With the corner between the outer peripheral surface 240 and the bottom surface 242 in the second recess portion 24 being chamfered, when the connecting portion 41 of the auxiliary member 4 is pressed and joined to the plate 2 at the time of manufacturing the ceramic heater 10, stress generated in the second recess portion 24 of the plate 2 is prevented from concentrating at the corner between the outer peripheral surface 240 and the bottom surface 242. Accordingly, the risk of damage to the second recess portion 24 can be reduced.

Referring to FIG. 30, a corner between the side surface 232 and the bottom surface 233 in the first recess portion 23 may also be chamfered, similarly to the second recess portion 24. Accordingly, when the lid portion 40 of the auxiliary member 4 is pressed and joined to the plate 2 at the time of manufacturing the ceramic heater 10, stress generated in the first recess portion 23 of the plate 2 is prevented from concentrating at the corner between the side surface 232 and the bottom surface 233. Thus, the risk of damage to the first recess portion 23 can be reduced.

Referring to FIG. 30 and FIG. 31, in the ceramic heater 11 according to the third embodiment, when the connecting portion 41 of the auxiliary member 4 is fitted into the second recess portion 24, the bottom surface 242 of the second recess portion 24 is exposed on the inner side of the connecting portion 41. On the second main surface 21 side of the plate 2, no protrusion 25 is present on the inner side of the connecting portion 41, and a space S surrounded by the connecting portion 41 is present on the bottom surface 242 of the second recess portion 24.

Referring to FIG. 23, the groove 26 is formed in the bottom surface 220 of the recess portion 22 (the bottom surface 233 of the first recess portion 23 and the bottom surface 242 of the second recess portion 24) of the plate 2 so as to be recessed toward the first main surface 20. Further, the groove 26 extends from an inner area of the shaft 3 to an outer area of the shaft 3 and up to the position closer to the outer periphery of the second main surface 21, on the second main surface 21 side of the plate 2. That is, out of a start end 260 and a terminal end 261, which are both ends of the groove 26, the start end 260 is located on the inner side of the shaft 3. The terminal end 261 is located on the outer side of the shaft 3, and is located closer to the outer periphery of the second main surface 21. The first thermocouple 14 is inserted from an inner portion 263 of the groove 26 located on the inner side of the shaft 3, and is then caused to pass through an outer portion 262 of the groove 26 located on the outer side of the shaft 3, to thereby be inserted up to the vicinity of the outer periphery of the plate 2. In this embodiment, the groove 26 extends up to the position closer to the outer periphery of the second main surface 21, and the terminal end 261 of the groove 26 is located closer to the outer periphery of the second main surface 21, but the terminal end 261 of the groove 26 may be located away from the outer periphery of the second main surface 21 as long as the terminal end 261 is located on the outer side of the shaft 3.

Referring to FIG. 30, the auxiliary member 4 is fitted into the recess portion 22 formed in the plate 2 to be joined to the plate 2 in the recess portion 22, similarly to the first embodiment. Although not particularly limited, the second surface 402, which is the front surface of the lid portion 40, is preferably flush with the second main surface 21 of the plate 2. The second surface 413, which is the front surface of the connecting portion 41, may protrude from the second main surface 21 of the plate 2 or may be flush with the second main surface 21 of the plate 2. Then, the distal end portion 32 of the shaft 3 is joined to the connecting portion 41 of the auxiliary member 4, so that the plate 2, the auxiliary member 4, and the shaft 3 are integrated.

In the ceramic heater 11 according to the third embodiment, with the auxiliary member 4 being fitted into the recess portion 22, positioning of the auxiliary member 4 relative to the plate 2 is facilitated, and accordingly, positioning of the shaft 3 relative to the plate 2 is facilitated.

Further, referring to FIG. 30 and FIG. 31, regarding the connecting portion 41 of the auxiliary member 4 fitted into the recess portion 22 of the plate 2, no protrusion 25 of the plate 2 is present on the inner side of the connecting portion 41, and the space S is present. Accordingly, heat transfer from the plate 2 to the auxiliary member 4 due to thermal radiation from the protrusion 25 can be prevented. Referring to FIG. 9, in the ceramic heater 1 according to the first embodiment, the gap G is formed between the inner peripheral surface 411 of the connecting portion 41 and the inner peripheral surface 241 of the second recess portion 24 (the peripheral surface of the protrusion 25) in order to suppress heat transfer from the plate 2 to the auxiliary member 4, so that lateral heat conduction in which heat from the plate 2 is directly transferred from the plate 2 to the auxiliary member 4 is suppressed. In the ceramic heater 11 according to the third embodiment, no protrusion 25 is present, and the space S larger than the gap G is formed, on the inner side of the connecting portion 41. Accordingly, lateral heat conduction in which the heat of the plate 2 is directly transferred from the plate 2 to the auxiliary member 4 via the protrusion 25 does not occur, and the heat of the plate 2 is also prevented from being transferred from the plate 2 to the auxiliary member 4 due to thermal radiation from the protrusion 25. As a result, transfer of the heat of the plate 2 to the shaft 3 via the auxiliary member 4 is effectively suppressed. Accordingly, the temperature uniformity of the first main surface 20 of the plate 2 on which the wafer is to be placed can be further improved. In addition, with no protrusion 25 being formed on the plate 2, the time required for raising the temperature of the plate 2 to a desired temperature is accordingly shortened.

Further, referring to FIG. 30 and FIG. 31, with no protrusion 25 of the plate 2 being present on the inner side of the connecting portion 41, when the connecting portion 41 is pressed and joined to the plate 2 at the time of manufacturing the ceramic heater 10, stress generated in the second recess portion 24 of the plate 2 is prevented from concentrating at the corner between the inner peripheral surface 241 (the peripheral surface of the protrusion 25) and the bottom surface 242, as in the ceramic heater 1 according to the first embodiment illustrated in FIG. 9. Accordingly, the risk of damage to the second recess portion 24 can be reduced.

### Other Modification Example 1

In the ceramic heater 1 according to the first embodiment described above, the corner between the side surface 232 and the bottom surface 233 in the first recess portion 23 and the corner between the outer peripheral surface 240 and the bottom surface 242 in the second recess portion 24 may be chamfered, similarly to the third embodiment. Similarly, the corner between the inner peripheral surface 241 and the bottom surface 242 in the second recess portion 24 may also be chamfered. Accordingly, the risk of damage to the first recess portion 23 and the second recess portion 24 of the plate 2 at the time of manufacturing the ceramic heater 10 can be reduced.

### Other Modification Example 2

In the ceramic heater 1 according to the first embodiment described above, the front surface of the protrusion 25 surrounded by the second recess portion 24 is located at the same height as in the second main surface 21 of the plate 2, but may be located lower toward the first main surface 20 side as compared to the second main surface 21 of the plate 2, and a space surrounded by the inner peripheral surface 411 of the connecting portion 41 may be defined on the front surface of the protrusion 25. According to this modification example, transfer of heat of the plate 2 to the auxiliary member 4 due to thermal radiation from the protrusion 25 can be suppressed. Accordingly, transfer of the heat of the plate 2 to the shaft 3 via the auxiliary member 4 is satisfactorily suppressed, so that the temperature uniformity of the first main surface 20 on which the wafer of the plate 2 is to be placed can be further improved.

### Other Modification Example 3

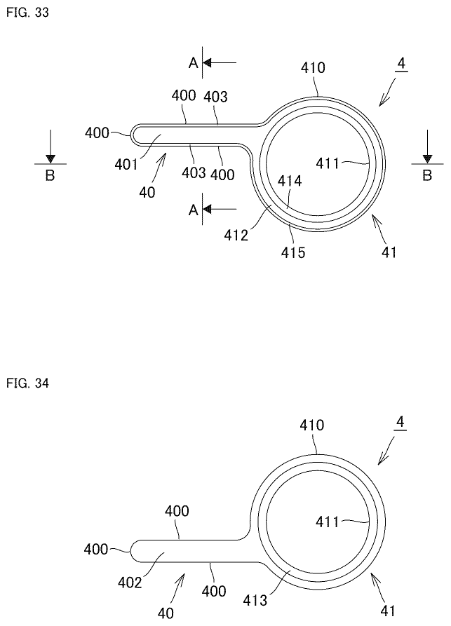

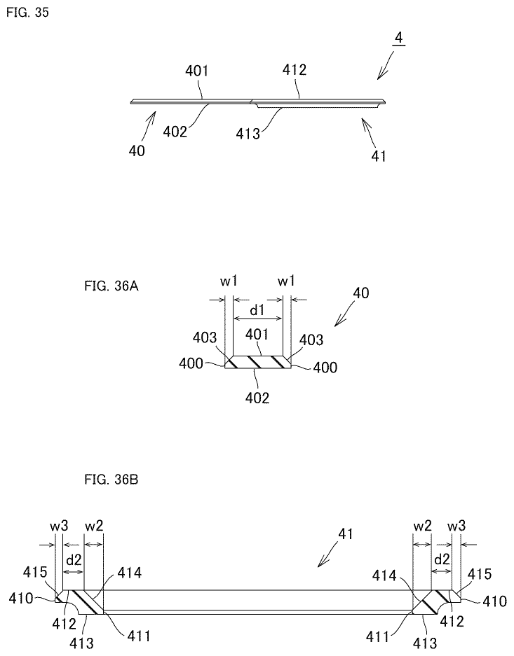

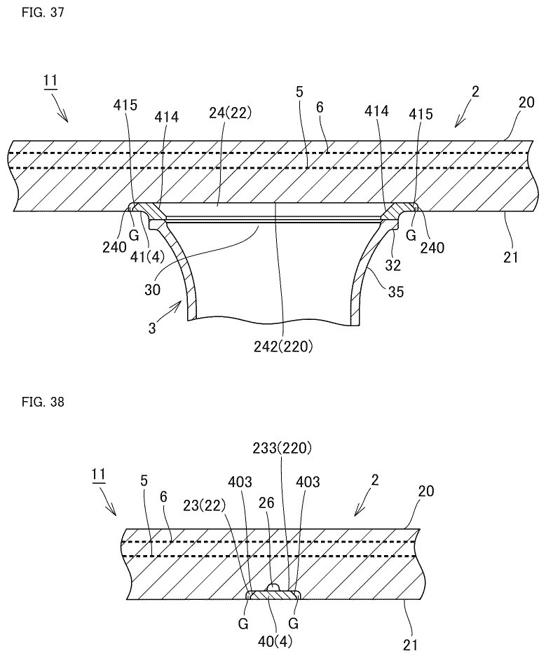

In the ceramic heaters 1, 10, and 11 according to the first, second, and third embodiments described above, at least a portion on the first surface 401 side, which is allowed to abut against the plate 2, of the lid portion 40 of the auxiliary member 4, and at least a portion on the first surface 412 side, which is allowed to abut against the plate 2, of the connecting portion 41 of the auxiliary member 4 may each have a tapered shape. FIG. 33 is a plan view of a modification example of the auxiliary member 4. FIG. 34 is a bottom view of the modification example of the auxiliary member 4. FIG. 35 is a front view of the modification example of the auxiliary member 4. FIG. 36A and FIG. 36B are sectional views of the modification example of the auxiliary member 4. FIG. 37 and FIG. 38 are enlarged sectional views for illustrating a part of the ceramic heater 11 according to the third embodiment including the modification example of the auxiliary member 4.

For example, referring to FIG. 36A, in the lid portion 40 of the auxiliary member 4, at least a portion on the first surface 401 side of at least one of a pair of opposing side surfaces 400 of the lid portion 40 is inclined inward to form an inclined surface 403, so that at least a portion on the first surface 401 side of the lid portion 40 can be formed into a tapered shape. The side surface 400 of the lid portion 40 may be inclined over the entire length from the end on the second surface 402 side to the end on the first surface 401 side, but in this case, the corner between the side surface 400 and the second surface 402, which does not abut against the plate 2, becomes sharply pointed at an acute angle, resulting in that the lid portion 40 has a shape of being easily damaged, such as chipping of the corner. Accordingly, it is preferred that only a portion on the first surface 401 side of the side surface 400 of the lid portion 40 be the inclined surface 403. The width d1 of the first surface 401 is preferably 15 mm or more in order to strengthen joining between the lid portion 40 and the plate 2.

At least a portion on the first surface 401 side of the lid portion 40 described above is formed into a tapered shape by C-chamfering the corner between the first surface 401 and the side surface 400, but may be formed into a tapered shape by R-chamfering the corner between the first surface 401 and the side surface 400. That is, the side surface 400 of the lid portion 40 is not always required to be linearly inclined, and may be curvilinearly inclined.

For example, referring to FIG. 36B, in the connecting portion 41 of the auxiliary member 4, a portion on the first surface 412 side of the inner peripheral surface 411 of the connecting portion 41 is inclined outward, that is, toward the outer peripheral surface 410 of the connecting portion 41, to form a first inclined surface 414, so that at least a portion on the first surface 412 side of the connecting portion 41 can be formed into a tapered shape. Alternatively or in addition thereto, a portion on the first surface 412 side of the outer peripheral surface 410 of the connecting portion 41 is inclined inward, that is, toward the inner peripheral surface 411 of the connecting portion 41, to form a second inclined surface 415, so that at least a portion on the first surface 412 side of the connecting portion 41 can be formed into a tapered shape. The outer peripheral surface 410 and the inner peripheral surface 411 of the connecting portion 41 may be inclined over the entire length from the end on the second surface 413 side to the end on the first surface 412 side, but in this case, a corner between the outer peripheral surface 410 and the inner peripheral surface 411 and the second surface 413, which does not abut against the plate 2, becomes sharply pointed at an acute angle, resulting in that the connecting portion 41 has a shape of being easily damaged, such as chipping of the corner. Accordingly, it is preferred that only a portion on the first surface 412 side of the outer peripheral surface 410 of the connecting portion 41 be the inclined surface 415, and a portion on the first surface 412 side of the inner peripheral surface 411 of the connecting portion 41 be the inclined surface 414. The width d2 of the first surface 412 is preferably 5 mm or more in order to strengthen joining between the connecting portion 41 and the plate 2.

When the area of the first surfaces 401 and 412, which are allowed to abut against the plate 2, of the lid portion 40 and the connecting portion 41 of the auxiliary member 4 is small, longitudinal heat conduction in which the heat of the plate 2 is directly transferred from the plate 2 to the auxiliary member 4 is suppressed. Accordingly, the heat of the plate 2 hardly transfers to the shaft 3 via the auxiliary member 4, resulting in that the temperature uniformity of the first main surface 20 on which the wafer of the plate 2 is to be placed can be further improved.

At least a portion on the first surface 412 side of the connecting portion 41 described above is formed into a tapered shape by C-chamfering the corner between the first surface 412 and the inner peripheral surface 411 or the corner between the first surface 412 and the outer peripheral surface 410, but may be formed into a tapered shape by R-chamfering the corner between the first surface 412 and the inner peripheral surface 411 or the corner between the first surface 412 and the outer peripheral surface 410. That is, the inner peripheral surface 411 and the outer peripheral surface 410 of the connecting portion 41 are not always required to be linearly inclined, and may be curvilinearly inclined.

With the corner between the first surface 401 and the side surface 400 in the lid portion 40 being chamfered, and the corner between the first surface 412 and the inner peripheral surface 411 or the corner between the first surface 412 and the outer peripheral surface 410 in the connecting portion 41 being chamfered, when the lid portion 40 and the connecting portion 41 of the auxiliary member 4 are pressed and joined to the plate 2 at the time of manufacturing the ceramic heater 10, stress generated in the lid portion 40 and the connecting portion 41 is prevented from concentrating at the above-mentioned corners. Accordingly, the risk of damage to the lid portion 40 and the connecting portion 41 of the auxiliary member 4 can be reduced.

From the viewpoint of preventing stress concentration at such corners, it is preferred that, in the lid portion 40, the corner between each of the pair of opposing side surfaces 400 and the first surface 401 be chamfered. Further, it is preferred that, in the connecting portion 41, the corner between each of the outer peripheral surface 410 and the inner peripheral surface 411 and the first surface 412 be chamfered.

Further, from the viewpoint of effectively preventing stress concentration at the above-mentioned corners, it is preferred that the inclined surfaces 403, 414, and 415 formed by chamfering be inclined over a long distance. The phrase “the inclined surfaces 403, 414, and 415 are inclined over a long distance” as used herein means that, in the lid portion 40, referring to FIG. 36A, the distance w1 over which the inclined surface 403 is inclined is long. Specifically, the distance w1 is a distance by which the inclined surface 403 protrudes inward from the side surface 400 due to the inclination, that is, a distance along the horizontal direction between the end of the inclined surface 403 on the side surface 400 side and the end of the inclined surface 403 on the first surface 401 side. The phrase “distance along the horizontal direction” refers to a distance along a direction parallel to the first surface 401 in the cross section of the lid portion 40, and refers to a distance along the width direction in the plan view of the lid portion 40.

The phrase “the inclined surfaces 403, 414, and 415 are inclined over a long distance” as used herein means that, in the connecting portion 41, referring to FIG. 36B, the distance w2 over which the first inclined surface 414 is inclined and the distance w3 over which the second inclined surface 415 is inclined are long. Specifically, the distance w2 is a distance by which the first inclined surface 414 protrudes outward from the inner peripheral surface 411 due to the inclination, that is, a distance along the horizontal direction between the end of the first inclined surface 414 on the inner peripheral surface 411 side and the end of the first inclined surface 414 on the first surface 412 side. Further, the distance w3 is a distance by which the second inclined surface 415 protrudes inward from the outer peripheral surface 410 due to the inclination, that is, a horizontal distance between the end of the second inclined surface 415 on the outer peripheral surface 410 side and the end of the second inclined surface 415 on the first surface 412 side. The phrase “distance along the horizontal direction” refers to a distance along a direction parallel to the first surface 412 in the cross section of the connecting portion 41, and refers to a distance along the radial direction of the connecting portion 41 having an annular shape, in plan view of the connecting portion 41.

The distances w1, w2, and w3 over which the inclined surfaces 403, 414, and 415 are inclined can be set longer by increasing the inclination angle of the inclined surfaces 403, 414, and 415, or by increasing the height of the inclined surfaces 403, 414, and 415 (a vertical distance between both ends of each of the inclined surfaces 403, 414, and 415).

Regarding the connecting portion 41, referring to FIG. 36B, it is preferred that the first inclined surface 414 be inclined over a longer distance as compared to the second inclined surface 415, that is, the distance w2 over which the first inclined surface 414 is inclined be longer than the distance w3 over which the second inclined surface 415 is inclined. Specifically, when the inclination angle of the first inclined surface 414, that is, an angle at which the first inclined surface 414 is inclined with respect to the direction parallel to the first surface 412 in the cross section of the connecting portion 41, and the inclination angle of the second inclined surface 415, that is, an angle at which the second inclined surface 415 is inclined with respect to the direction parallel to the first surface 412 in the cross section of the connecting portion 41, are identical to each other, it is preferred that the height of the first inclined surface 414, that is, a distance along the vertical direction between the end of the first inclined surface 414 on the inner peripheral surface 411 side and the end of the first inclined surface 414 on the first surface 412 side, be set longer than the height of the second inclined surface 415, that is, a vertical distance between the end of the second inclined surface 415 on the outer peripheral surface 410 side and the end of the second inclined surface 415 on the first surface 412 side. In the connecting portion 41, when the distance w3 over which the second inclined surface 415 is inclined is set longer, the corner between the outer peripheral surface 410 and the second surface 413 tends to have an acute angle at which the corner is easily damaged. With the distance w2 over which the first inclined surface 414 is inclined being set longer than the distance w3 over which the second inclined surface 415 is inclined, the connecting portion 41 can be formed into a shape such that the corner between the outer peripheral surface 410 and the second surface 413 does not have an acute angle, while securing the width d2 of the first surface 412 and setting the inclined surfaces 414 and 415 effective for preventing stress concentration as large as possible.

### Other Modification Example 4

In the ceramic heaters 1 and 11 according to the first and third embodiments described above, the gap G is formed between the side surface of the auxiliary member 4 (the side surfaces 400 of the lid portion 40 and the outer peripheral surface 410 of the connecting portion 41) fitted into the recess portion 22 of the plate 2 and the side surface of the recess portion 22 (the side surfaces 232 of the first recess portion 23 and the outer peripheral surface 240 of the second recess portion 24), but the gap G may be filled. Further, in the ceramic heater 1 according to the first embodiment described above, the gap G is also formed between the inner peripheral surface 411 of the connecting portion 41 and the inner peripheral surface 241 of the second recess portion 24, but the gap G may be filled.

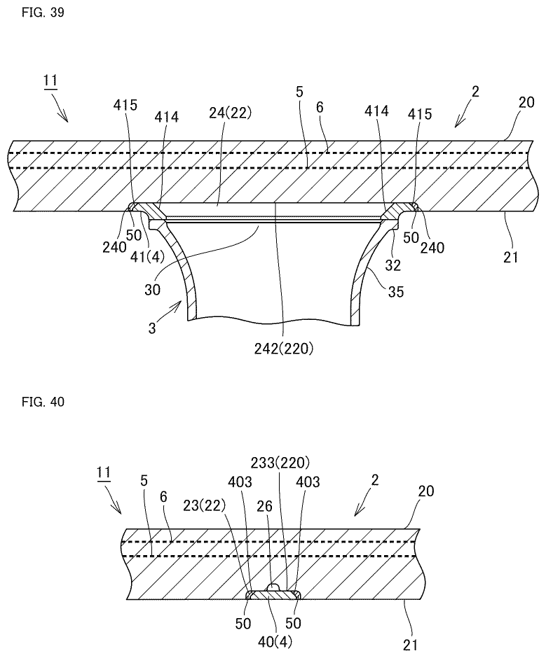

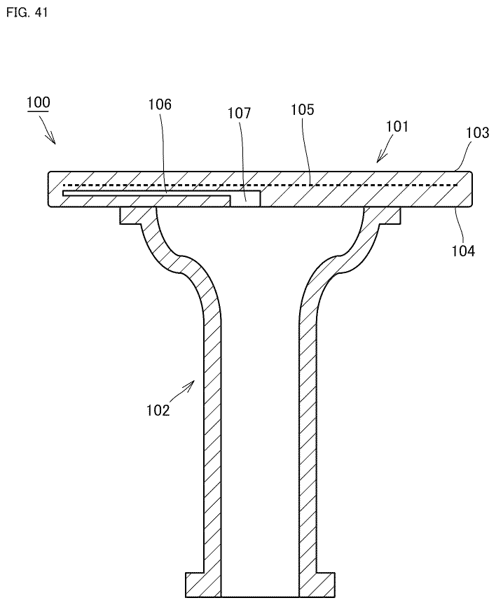

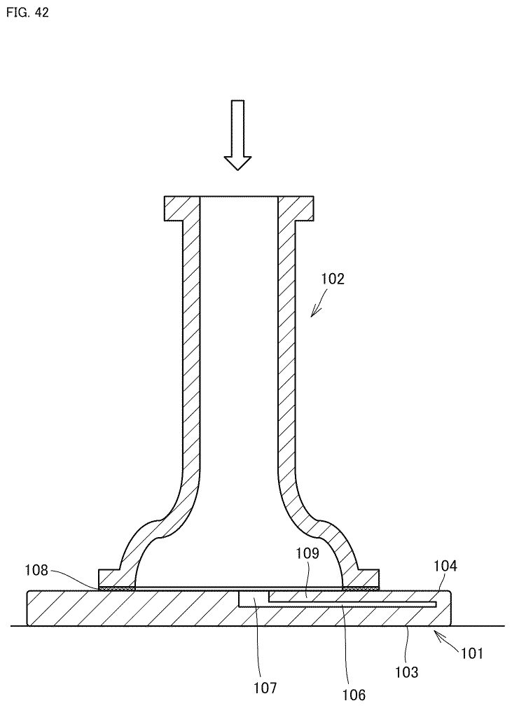

FIG. 39 and FIG. 40 are enlarged sectional views for illustrating a part of the ceramic heater 11 according to the third embodiment in which the gap G is filled with a filling material 50. Ceramics, a resin, or the like is used for the filling material 50. The gap G is filled with the filling material 50 by, for example, filling the gap G with ceramic powder of the same material as that of the plate 2 and firing the ceramic powder. Alternatively, the gap G is filled with the filling material 50 by filling the gap G with a liquid thermosetting resin such as an epoxy resin or a silicone resin and curing the resin. The resin may be a composite resin containing a filler such as ceramics or a metal.

When the gap G is filled with the filling material 50, the risk of unrequired substances, such as machining chips and dust, accumulating in the gap G in the manufactured ceramic heaters 1 and 10 can be reduced. For example, at the time of performing processing, such as chemical vapor deposition (CVD) or etching, on a wafer in a semiconductor manufacturing apparatus, when unrequired substances are accumulated in the gap G of the ceramic heaters 1 and 10, there is a concern that the unrequired substances may scatter toward the wafer during wafer processing and adversely affect the wafer processing. Further, when a gas used for the wafer processing enters the gap G and corrosion occurs at the joining surface between the auxiliary member 4 and the plate 2, there is a concern that the joining strength between the auxiliary member 4 and the plate 2 may decrease. When the gap G is filled with the filling material 50, the above-mentioned concerns can be eliminated. Whether to fill the gap G with the filling material 50 or to leave the gap G as it is without filling the gap G with the filling material 50 can be appropriately selected in consideration of the respective advantages.

### Other Modification Example 5

In the ceramic heaters 1 and 10 according to the first and second embodiments described above, the connecting portion 41 of the auxiliary member 4 is a ring plate having a circular annular shape, but may be a solid disc. In this case, a through hole in communication with the groove 26 formed in the plate 2 is formed in the connecting portion 41. Accordingly, the first thermocouple 14 is inserted from the through hole of the connecting portion 41, and is then caused to pass through the groove 26 of the plate 2, to thereby be inserted up to the vicinity of the outer periphery of the plate 2. When the connecting portion 41 of the auxiliary member 4 is a ring plate having a circular annular shape, as compared to the case of a solid disc, the volume of the auxiliary member 4 can be decreased, and a ratio of the auxiliary member 4 to the entire plate 2 including the auxiliary member 4 is reduced. Also in the ceramic heater 11 according to the third embodiment, the connecting portion 41 of the auxiliary member 4 may be a solid disc.

### Other Modification Example 6

In the ceramic heaters 1 and 10 according to the first and second embodiments described above, description has been given as an example of the configuration in which one groove 26 is formed in the plate 2, and the auxiliary member 4 accordingly includes one lid portion 40. However, the number of grooves 26 formed in the plate 2 is not limited to one, and the auxiliary member 4 may include a plurality of lid portions 40 depending on the number of grooves 26. In this case, the plurality of lid portions 40 may extend in different directions from different positions on one connecting portion 41. Also in the ceramic heater 11 according to the third embodiment, the number of grooves 26 formed in the plate 2 is not limited to one, and the auxiliary member 4 may include a plurality of lid portions 40 depending on the number of grooves 26.

It is to be understood that the embodiments disclosed herein are merely examples in all aspects and in no way intended to limit the present disclosure in any aspect. The scope of the present invention is defined by the appended claims and not by the above description, and it is intended that the present invention encompasses all modifications made within the scope and spirit equivalent to those of the appended claims.

1. A ceramic heater, comprising:
a plate having a plate shape, which includes:
a first main surface, on which a wafer is to be placed;
a second main surface spaced apart from the first main surface in a thickness direction; and
a resistance heating element built into the plate and configured to generate heat through energization;
a shaft having a cylindrical shape, which has a first opening and a second opening that are respectively located at both ends in an axial direction, and which is configured to support the plate at the second main surface; and
an auxiliary member having a plate shape and configured to be joined to the plate,
wherein the plate has a groove, which is recessed from the second main surface toward the first main surface, and which extends from a start end located on an inner side of the shaft to a terminal end located on an outer side of the shaft,
wherein the auxiliary member includes:
a lid portion, which extends along an outer portion of the groove that is a portion located on the outer side of the shaft, and which is configured to cover the outer portion; and
a connecting portion having an annular shape, which is configured to be sandwiched between the plate and the shaft, and to which a distal end portion of the shaft that is a portion surrounding the first opening is allowed to be joined,
wherein the plate has a recess portion, which is recessed from the second main surface toward the first main surface, and into which the auxiliary member is allowed to be fitted,
wherein the recess portion includes:
a first recess portion, into which the lid portion is allowed to be fitted; and
a second recess portion, into which the connecting portion is allowed to be fitted, and which is continuous with the first recess portion,
wherein the second recess portion is formed in an annular shape so as to have an inner peripheral surface that faces an inner peripheral surface of the connecting portion,
wherein the groove includes:
a first groove portion formed in a bottom surface of the first recess portion and a bottom surface of the second recess portion so as to be recessed toward the first main surface; and
a second groove portion, which is formed in the second main surface of the plate on the inner side of the shaft so as to be recessed toward the first main surface, and which is in communication with the first groove portion,
wherein at least a portion on a first surface side, which is allowed to abut against the plate, of the connecting portion of the auxiliary member has a tapered shape,
wherein at least a portion on the first surface side of the inner peripheral surface of the connecting portion is a first inclined surface inclined toward an outer peripheral surface of the connecting portion,
wherein at least a portion on the first surface side of the outer peripheral surface of the connecting portion is a second inclined surface inclined toward the inner peripheral surface of the connecting portion, and
wherein the first inclined surface is inclined over a longer distance as compared to the second inclined surface.

2. A ceramic heater, comprising:
a plate having a plate shape, which includes:
a first main surface, on which a wafer is to be placed;
a second main surface spaced apart from the first main surface in a thickness direction; and
a resistance heating element built into the plate and configured to generate heat through energization;
a shaft having a cylindrical shape, which has a first opening and a second opening that are respectively located at both ends in an axial direction, and which is configured to support the plate at the second main surface; and
an auxiliary member having a plate shape and configured to be joined to the plate,
wherein the plate has a groove, which is recessed from the second main surface toward the first main surface, and which extends from a start end located on an inner side of the shaft to a terminal end located on an outer side of the shaft,
wherein the auxiliary member includes:
a lid portion, which extends along an outer portion of the groove that is a portion located on the outer side of the shaft, and which is configured to cover the outer portion; and
a connecting portion having an annular shape, which is configured to be sandwiched between the plate and the shaft, and to which a distal end portion of the shaft that is a portion surrounding the first opening is allowed to be joined,
wherein the plate has a recess portion, which is recessed from the second main surface toward the first main surface, and into which the auxiliary member is allowed to be fitted,
wherein the recess portion includes:
a first recess portion, into which the lid portion is allowed to be fitted; and
a second recess portion, into which the connecting portion is allowed to be fitted, and which is continuous with the first recess portion,
wherein the second recess portion is formed in an annular shape so as to have an inner peripheral surface that faces an inner peripheral surface of the connecting portion,
wherein the groove includes:
a first groove portion formed in a bottom surface of the first recess portion and a bottom surface of the second recess portion so as to be recessed toward the first main surface; and
a second groove portion formed in the second main surface of the plate on the inner side of the shaft so as to be recessed toward the first main surface, and which is in communication with the first groove portion,
wherein a gap is defined in at least one of at least a portion between a side surface of the auxiliary member and a side surface of the recess portion, or at least a portion between the inner peripheral surface of the connecting portion and the inner peripheral surface of the second recess portion,
wherein the gap is filled with a filling material, and
wherein the filling material is a resin or ceramics.

3. The ceramic heater according to claim 1, wherein a gap is defined in at least a portion between a side surface of the auxiliary member and a side surface of the recess portion.

4. The ceramic heater according to claim 1, wherein a gap is defined in at least a portion between the inner peripheral surface of the connecting portion and the inner peripheral surface of the second recess portion.

5. A ceramic heater, comprising:
a plate having a plate shape, which includes:
a first main surface, on which a wafer is to be placed;
a second main surface spaced apart from the first main surface in a thickness direction; and
a resistance heating element built into the plate and configured to generate heat through energization;
a shaft having a cylindrical shape, which has a first opening and a second opening that are respectively located at both ends in an axial direction, and which is configured to support the plate at the second main surface; and
an auxiliary member having a plate shape and configured to be joined to the plate,
wherein the plate has a groove, which is recessed from the second main surface toward the first main surface, and which extends from a start end located on an inner side of the shaft to a terminal end located on an outer side of the shaft,
wherein the auxiliary member includes:
a lid portion, which extends along an outer portion of the groove that is a portion located on the outer side of the shaft, and which is configured to cover the outer portion; and
a connecting portion having an annular shape, which is configured to be sandwiched between the plate and the shaft, and to which a distal end portion of the shaft that is a portion surrounding the first opening is allowed to be joined,
wherein the plate has a recess portion, which is recessed from the second main surface toward the first main surface, and into which the auxiliary member is allowed to be fitted,
wherein the recess portion includes:
a first recess portion, into which the lid portion is allowed to be fitted; and
a second recess portion, into which the connecting portion is allowed to be fitted, and which is continuous with the first recess portion,
wherein the second recess portion is formed so as to have a flat bottom surface, against which the connecting portion is allowed to abut, and an outer peripheral surface that faces an outer peripheral surface of the connecting portion,
wherein a space is present on an inner side of the connecting portion on the flat bottom surface, and
wherein the groove is formed in a bottom surface of the first recess portion and the bottom surface of the second recess portion so as to be recessed toward the first main surface.

6. The ceramic heater according to claim 2, wherein at least a portion on a first surface side, which is allowed to abut against the plate, of at least one of the lid portion or the connecting portion of the auxiliary member has a tapered shape.

7. The ceramic heater according to claim 5, wherein at least a portion on a first surface side, which is allowed to abut against the plate, of at least one of the lid portion or the connecting portion of the auxiliary member has a tapered shape.

8. The ceramic heater according to claim 6, wherein at least a portion on the first surface side of an inner peripheral surface of the connecting portion is a first inclined surface inclined toward the outer peripheral surface of the connecting portion.

9. The ceramic heater according to claim 7, wherein at least a portion on the first surface side of an inner peripheral surface of the connecting portion is a first inclined surface inclined toward the outer peripheral surface of the connecting portion.

10. The ceramic heater according to claim 8,
wherein at least a portion on the first surface side of the outer peripheral surface of the connecting portion is a second inclined surface inclined toward the inner peripheral surface of the connecting portion, and
wherein the first inclined surface is inclined over a longer distance as compared to the second inclined surface.

11. The ceramic heater according to claim 9,
wherein at least a portion on the first surface side of the outer peripheral surface of the connecting portion is a second inclined surface inclined toward the inner peripheral surface of the connecting portion, and
wherein the first inclined surface is inclined over a longer distance as compared to the second inclined surface.

12. The ceramic heater according to claim 3, wherein the gap is filled with a filling material.

13. The ceramic heater according to claim 4, wherein the gap is filled with a filling material.

14. The ceramic heater according to claim 1,
wherein the plate and the shaft each contain aluminum nitride as a main component, and
wherein the auxiliary member contains aluminum nitride as a main component, and is free of yttria.

15. The ceramic heater according to claim 2,
wherein the plate and the shaft each contain aluminum nitride as a main component, and
wherein the auxiliary member contains aluminum nitride as a main component, and is free of yttria.

16. The ceramic heater according to claim 3,
wherein the plate and the shaft each contain aluminum nitride as a main component, and
wherein the auxiliary member contains aluminum nitride as a main component, and is free of yttria.

17. The ceramic heater according to claim 4,
wherein the plate and the shaft each contain aluminum nitride as a main component, and
wherein the auxiliary member contains aluminum nitride as a main component, and is free of yttria.

18. The ceramic heater according to claim 5,
wherein the plate and the shaft each contain aluminum nitride as a main component, and
wherein the auxiliary member contains aluminum nitride as a main component, and is free of yttria.

19. A method of manufacturing a ceramic heater, the method comprising:
forming, in a plate having a plate shape, which includes a resistance heating element built into the plate and configured to generate heat through energization, and contains aluminum nitride as a main component, a groove that is recessed from a second main surface toward a first main surface out of the first main surface and the second main surface of the plate, which are spaced apart from each other in a thickness direction, and that extends from the center of the second main surface toward an outer periphery of the second main surface;
installing, onto the plate via a flux containing a rare earth component, an auxiliary member having a plate shape, which includes a lid portion and a connecting portion having an annular shape, contains aluminum nitride as a main component, and is free of yttria, so that an outer portion of the groove, which is a portion near the outer periphery of the second main surface, is covered with the lid portion that extends along the outer portion, and an inner portion of the groove, which is a portion near the center of the second main surface, is located on an inner side of the connecting portion;
installing, onto the auxiliary member via the flux, a shaft having a cylindrical shape, which contains aluminum nitride as a main component, so that a distal end portion of the shaft, which is an area surrounding a first opening out of the first opening and a second opening of the shaft that are respectively located at both ends of the shaft in an axial direction, abuts against the connecting portion; and
simultaneously joining the shaft and the connecting portion of the auxiliary member, and the connecting portion of the auxiliary member and the plate to each other, while applying a pressure to the shaft, and joining the lid portion of the auxiliary member and the plate to each other while applying a load to the lid portion of the auxiliary member by a pressing member.

20. The method of manufacturing a ceramic heater according to claim 19, wherein at least a portion on a first surface side, which is allowed to abut against the plate, of an inner peripheral surface of the connecting portion is inclined toward an outer peripheral surface of the connecting portion.
